(19) United States
(12) Patent Application Publication
(10) Pub. No.: US 2008/0175785 A1
(43) Pub. Date: Jul. 24, 2008

(54) CHEMICAL VAPOR DEPOSITION OF CARBON NANOTUBES ON STRUCTURES AND SUBSTRATES

(75) Inventors: Somenath Mitra, Bridgewater, NJ (US); Mahesh K. Karwa, Exton, PA (US)

Correspondence Address: MCCARTER & ENGLISH , LLP STAMFORD OFFICE, FINANCIAL CENTRE , SUITE 304A, 695 EAST MAIN STREET, STAMFORD, CT, 06901-2138, US

(73) Assignee: NEW JERSEY INSTITUTE OF TECHNOLOGY, Newark, NJ (US)

(21) Appl. No.: 11/851,688

(22) Filed: Sep. 7, 2007

Related U.S. Application Data
(60) Provisional application No. 60/843,269, filed on Sep. 8, 2006.

(51) Int. Cl. C01B 31/00; C23C 16/00

(52) U.S. Cl. 423/445 B; 427/249.1

(57) ABSTRACT

Apparatus, systems, and methods are provided for the production and application of carbon nanotubes (CNTs) on structures. Disclosed embodiments relate to apparatus, systems, and methods for the production of CNTs in an open tubular configuration on the inside surface of a steel capillary tubing. Disclosed embodiments of means for the production of CNTs include, self-assembly through a catalytic chemical vapor deposition (CVD) process. Applications of the apparatus, systems, and methods disclosed generally relate to sorbency, and more particularly, include adsorption, separation, and chromatographical application. Disclosed embodiments include apparatus, systems, and methods, for the production of high performance stationary phases of CNTs with advantageous temperate stability for high resolution chromatographical applications.

### CROSS-REFERENCE TO RELATED APPLICATIONS

The present application claims the benefit of a co-pending, commonly assigned provisional patent application entitled “Self-Assembly of Carbon Nanotubes on Structures for Applications in Adsorption, Separation, and Chromatography,” which was filed on Sep. 8, 2006 and assigned Ser. No. 60/842,269. The entire contents of the foregoing provisional patent application are incorporated herein by reference.

### STATEMENT OF GOVERNMENTAL INTEREST

The United States government may hold license and/or other rights in this invention as a result of financial support provided by governmental agencies in the development of aspects of the invention. Parts of this work were supported by a grant from the US EPA STAR grant RD 830901.

### BACKGROUND

1. Technical Field

The present disclosure relates generally to the field of nanotechnology. More particularly, the present disclosure relates to the production of nano-materials, e.g., nanotubes, nanohorns, fullerenes nano-onions and nanocomposites. Exemplary embodiments of the present disclosure relate to the production of carbon nanotubes (CNTs), e.g., single wall nanotubes (SWNTs) and multiwall nanotubes (MWNTs). Exemplary embodiments of the present disclosure relate to the production, e.g., by self assembly, of CNTs on structures. Exemplary applications of the herein disclosed apparatus, systems and methods include novel CNT applications relating to sorbency, e.g., particle adsorption, particle separation and chromatography. In addition, production techniques for high performance stationary phases of CNTs with advantageous temperate stability for high resolution chromatographical applications are provided. Still further, production techniques for CNTs in an open tubular configuration on an inside surface of a substrate, e.g., steel capillary tubing, via a novel catalytic chemical vapor deposition (CVD) process are disclosed.

2. Background Art:

Carbon-based sorbents are used in a variety of industrial and laboratory scale applications, such as, adsorbents, gas cleaning, water treatment, pollution control and the separation of solutes. Such sorbents are also used extensively in analytical applications, such as chromatographic stationary phases. Consequently, developments in carbon-based sorbents have been an ongoing endeavor that has been of great interest to the scientific communities.

Carbon nanotubes (CNTs), e.g., multi wall nanotubes (MWNTs) and single wall nanotubes (SWNTs), are nanosized carbon-based sorbents characterized by high surface areas, large aspect ratios, and temperate stability (even at high temperatures). In general, CNTs possess advantageous mechanical, thermal and electrical properties, and are potentially useful in a wide range of applications, fields and industries.

SWNTs are considered the fundamental form of CNTs and are generally composed of a single hexagonal layer of carbon atoms (graphene sheet) that has been rolled up to form a seamless cylinder with a diameter in the nanometer order. A SWNT has the thickness of a single atom and possesses unique electronic properties arising from this dimensionality. Particular embodiments of CNTs may include two fullerene halves capping the ends of a SWNT and forming a closed cylindrical configuration.

Since CNTs can be synthesized in different forms, diameters, sizes, film thicknesses and with different functionalities that generally provide variable affinity and selectivity, CNTs can be used for the separation of a wide range of solutes. The combination of these elements with absorptive ability provides unique opportunities for the development of higher performance separation techniques that utilize the nanoscale interactions on a material known to have high thermal and mechanical stability. Therefore, CNTs are an important and effective alternative for highly selective, high temperature sorbents for chromatography.

In general CNTs can be found and/or produced in a variety of forms, e.g., open-ended, closed-ended, single shelled, concentrically shelled, spiral shelled, etc. The many different CNT configurations with their various chiralities are likely to open new frontiers, with applications including material science, electronics and molecular scale sensing and chromatographic analysis.

The ability to functionalize (chemically alter) a CNT can be particularly advantageous. Functionalization is generally accomplished by adding or attaching a functional group, polymer or molecule (e.g., biomolecules such as enzymes or proteins) to an original or underlying CNT structure. Functionalization may be achieved through various processes, including covalent attachment or immobilization of a polymer or other molecule and such functionalization can lead to development of new classes of material with specific physical and chemical properties. Thus, development of new approaches/techniques for functionalization of self-assembled CNTs would be particularly advantageous, e.g., resulting in an ability to controllably and predictably alter CNT properties relevant to separation, adsorption and chromatographical applications. Control of various CNT properties, e.g., polarity, hydrogen bonding tendencies, chemical affinities and the like, are of particular interest.

Prior to functionalization, CNTs possess no functional groups and are consequently quite inert. Limited reactivity arises due to the curvature induced stress from the non-planer sp² carbons and misaligned π orbitals. Some common approaches for functionalization include carboxylation, 1,3-dipolar cycloadditon, and amidation. A well known gas or liquid phase approach involves oxidizing atoms forming the tubular walls of a CNT, particularly near the tubular ends, resulting in formation of functional groups, e.g., F, —OH, —COOH, whereby chemical reactions can then occur.

As noted above, CNTs may also possess highly advantageous adsorption properties. Due to their adsorption properties, CNTs have been used in numerous specialized applications, e.g., as gas storage, pre-concentration of volatile organics (VOCs), removal of chemical and toxic wastes from water, and gas chromatography. Adsorption can occur on the outside surface, on the inner hollow cavity of CNTs, on the curved graphene planes, in the interstices between tubes that are bundled together, and on the inside when they are open-ended. There also exists the possibility of a molecular sieve effect on the interstitial spaces, where the large molecules could be excluded.

Chromatography is widely used for high-resolution separations and in quantitative analysis. Chromatographic separation involves the differential partitioning of solutes (or analytes) between a stationary and a mobile phase. A successful separation often depends on the ability to achieve separation within a reasonable time and at high resolutions. Typical solid phases for gas chromatography (GC) include porous polymers, silica and activated carbons, where adsorption is the dominant retention mechanism and high temperatures are often used to vary the retention in GC.

Carbon-based sorbent stationary phases may be used for separation of small organic and inorganic molecules, and are commercially available in various particle/pore sizes and with different specific surface areas. Typically, these particles are packed into a substrate, most commonly a tube, although open tubular carbon phases are also available. By way of example only, the substrate may be a hollow tubular structure or a tube packed with particles. In chromatography, the physical/chemical affinity between the sorbate and the sorbent is important so as to achieve separation within a reasonable time and at high resolution. High-performance stationary phases are referred to as such because of their ability to provide high resolution and maintain structural stability and performance at high temperatures. Accordingly, high-performance stationary phases are of significant importance in GC and other chromatographic analyses/applications.

Gas-solid chromatography (GSC) has evolved as a powerful analytical tool in the separation and analysis of gases and analytes with low boiling temperatures. GSC columns utilize the sorption of the solute on a solid stationary phase, as opposed to the partitioning in gas-liquid chromatography (GLC) as the dominant mechanism. The use of a solid sorbent film in place of a liquid stationary phase may allow the magnitude of the mass transfer term to be reduced and thereby allow high efficiency in gas-solid columns. Typical solid phases for gas chromatography (GC) include porous polymers (e.g., Porapak™ polymer), silica, molecular sieves, and activated carbons. The microporosity and large surface area (500-3000 m²/g) of such materials are primarily responsible for the enhanced sorption capacity. Traditionally, these solid phases are packed into a tube, as in a packed column, although open tubular phases (PLOT columns) are also available. Many of these sorbents have an upper temperature limit in operation of approximately 250-350° C., above which the sorbents begin to bleed.

In addition to the specific use of CNTs for chromatographical/sorbency-related application, the ability to generate and/or synthesize CNTs and other nanomaterials in a useful location relative to an appropriate structure is vitally important for the advancement of nanotechnology. Thus, since most chemical processing and separations are carried out in flow systems, it is important to study and develop apparatus, systems and methods relating to the production of nanomaterials relative to structures specific for integration into such flow-systems.

CNTs are generally synthesized by laser ablation, catalytic arc discharge, or chemical vapor deposition (CVD). The first two methods are excellent for large-scale production. SWNT synthesis is significantly more complex because MWNTs and amorphous carbon tend to grow preferentially during such synthesis. Selective growth of SWNTs generally requires precise preparation and deposition of a transition metal catalyst (e.g., Ni, Co, or Mo). An additional requirement for SWNT growth is the presence of these catalyst particles in angstrom size.

Synthesis of CNTs on bulk metallic surfaces is important for many industrial applications, including the use of CNTs in chromatography. For chromatographic purposes, the rationale behind using bulk metal as a substrate is the possibility of generating large amounts of metal nuclei in their nano-scale polycrystalline form on the surface. These centers would then act as catalyst sites for the growth of carbon nanotubes, thus eliminating the need for coating the surface with an additional exterior catalyst layer. Previously, the use of bulk metallic substrates resulted in the formation of only MWNTs.

Different kinds of growth mechanisms and models have been proposed to explain the formation of carbon nanotubes and carbon nanofibers. For example, a VLS (Vapor-Liquid-Solid) mechanism has been proposed wherein three defined steps are involved: (i) adsorption and decomposition of carbon containing species at the catalyst surface, (ii) dissolution and diffusion of these species into the molten catalyst, and (iii) precipitation of carbon as solid whiskers. Several researchers have also proposed tip growth and base type growth schemes as growth mechanisms based on their observations of encapsulated catalyst metal particles either at the tip or at the base of the nanotubes. The ‘tip-growth’ model proposes that a nanotube lengthens while carrying away a metal catalyst particle at its end. The carried-along particle supplies the carbon feedstock for the growth. The ‘base-growth’ model proposes that a nanotube lengthens with a particle-free closed end, and carbon feedstock is supplied from the base where the other end of the nanotube interfaces with the catalyst material. The tip growth scheme has been observed with large catalyst particles and with MWNT formation and the base growth scheme with the small nano particles and with SWNT formation. To account for the metallic catalyst particles at both the ends of a CNT, Chen et al. propose that the metal particles are in the liquid state and the stretching force causes them to elongate and finally break into two parts. (See, Chen X, Wang R, Xu J, Yu D., TEM investigation on the growth mechanism of carbon nanotubes synthesized by hot-filament chemical vapor deposition, Micron 2004; 35: 455-460). Chen et al. further suggest that the bottom part remains attached to the substrate, while the upper part remains encapsulated inside the CNTs.

Despite efforts to date, a need remains for apparatus, systems and methods that facilitate and/or promote the use of nanotubes in various applications, including adsorption, separation and chromatography. In addition, a need remains for apparatus, systems and methods that facilitate and/or promote combinations of nanotubes and underlying structures and/or substrates. Still further, a need remains for apparatus, systems and methods that facilitate and/or promote preservation of advantageous nano-characteristics of nanotubes, e.g., MWNTs, when combined with underlying structures and/or substrates. These and other needs are met by the apparatus, systems and methods disclosed herein.

### SUMMARY OF THE DISCLOSURE

The present disclosure provides apparatus, systems and methods for production of carbon nanotubes (CNTs), e.g., single wall nanotubes (SWNTs) and multi wall nanotubes (MWNTs), on structures and/or substrates. More particularly, the present disclosure provides apparatus, systems and methods for production of CNTs on structures/substrates for sorbency-related applications, e.g. fluid filtration, chromatography and the like. Thus, an exemplary embodiment of the present disclosure relates to the assembly or self-assembly of CNTs relative to a structure/substrate. In exemplary embodiments, CNT components are: (i) introduced into a system, (ii) exposed to a structure/substrate, (iii) synthesized into CNTs, and (iv) self-assembled relative to the structure/substrate. The self-assembly techniques/methods disclosed herein have particular applicability to adherence of CNTs relative to a substrate or large structure that takes the form of a hollow tubular structure or a tube packed with other particles. In exemplary embodiments disclosed herein, the structure/substrate may advantageously contain or include one or more metallic components.

Exemplary apparatus, systems and methods thus provide new and useful techniques for synthesizing CNTs on the inner surface of capillaries, e.g., steel capillaries, by catalytic chemical vapor deposition (CVD). CNTs may be assembled relative to the inside wall of a stainless steel tubing, e.g., type 316, using ethylene (C₂H₄) as the carbon source for direct CVD. Ethylene is an ideal (but not exclusive) carbon source for purposes of the present disclosure and consistently provides high density, uniform CNT layers that are useful for, inter alia, chromatography separation, e.g., gas chromatography (GC) separation.

In exemplary embodiments of the present disclosure, CNTs are assembled relative to a structure by CVD of an organic precursor. Examples of suitable organic precursors include but are not limited to ethylene, ethane, methane, carbon monoxide, ethanol, and methanol.

Exemplary embodiments of the present disclosure also employ the use of one or more catalysts to spark/promote CNT growth. In exemplary embodiments of the present disclosure, a metallic component of the substrate is used as the catalyst for CNT growth. In other exemplary embodiments, an external catalyst separate from the substrate is employed. Examples of suitable catalysts include but are not limited to iron, cobalt, molybdenum and nickel. External catalysts may also be introduced and prepared on the surface of the structure/substrate, or a catalyst may be deposited by electrodeposition. A single-step CVD process may be advantageously employed wherein dissolved cobalt and molybdenum salts (i.e., the catalysts) in ethanol (i.e., the precursor) are employed.

In exemplary embodiments of the present disclosure, the substrate may be completely or partially made of one or more metallic components. Exemplary metallic components include but are not limited to iron, steel, nickel, an austenitic nickel-based superalloy (e.g., Inconel™ alloy), and combinations thereof. In other exemplary embodiments, the substrate may be completely or partially made of one or more non-metallic components Exemplary non-metallic components include but are not limited to ceramics, plastic, glass and combinations thereof. The substrate may also be made of one or more non-metallic components which are infused or embedded with metallic components and/or ions.

According to the present disclosure, a metallic substrate surface may be conditioned by oxidation-reduction prior to the disclosed CVD process. Surface conditioning may be beneficial by enhancing and/or toning the metal surface with respect to its latent catalytic activity by forming nano-scale granular structures. Thus, surface oxidation by a flow of air may result in the breakup of the metallic surface to form fine granular structures which increase the surface area and act as catalyst sites. Another reason that conditioning may be beneficial is that the surface becomes structurally (microscopically) more homogenous, which may be advantageous for uniform growth of nanotubes.

In exemplary embodiments of the present disclosure, bulk metal may be used as the substrate for the purposes of forming CNTs. The use of bulk material allows for the generation of metallic nuclei in nano-scale polycrystalline form on the growth surface. These nuclei act as catalyst sites for the growth of carbon nanotubes, thus eliminating the potential need for coating the surface with an additional catalytic layer.

A catalyst and precursor, e.g. ethanol, may be advantageously injected through a capillary tube according to the present disclosure The capillary tube may be disposed in an oven, and the process may result in gas-phase synthesis of a layer of SWNTs relative to the interior of the capillary. In an exemplary embodiment of the present disclosure, CNTs are assembled relative to the inside wall of a stainless steel tubing, e.g. type 316, using C₂H₄ as the carbon source for direct CVD.

Temperature and precursor flow rates during the CVD process may play important roles in surface conditioning. Elevated temperatures, e.g. 700° C. as opposed to 500° C., typically generate thicker, smoother and more uniform surfaces with finer granular structures is more condensed areas of the tube. At higher precursor flow rates, the increased number of available precursor molecules results in the subjection of more molecules to decomposition at a given time. At the same time, higher flow rates allow the precursor molecules to travel further through the tube before decomposition.

Generally, in exemplary embodiments of the present disclosure, the thickness and the morphology of a CNT layer can be varied by altering CVD conditions. The ability to control thickness and morphology of a synthesized CNT layer further enables selective tuning for any type of phase separation, including gas, liquid or solid phase separations. In exemplary embodiments, the thickness of the resulting layer is controlled/determined by the time of deposition. In other exemplary embodiments, surface coverage and thickness of a CNT layer are controlled/determined by the flow rate of the carbon precursor, with a higher flow rate resulting in better coverage and greater thickness uniformity.

Non-tubular carbons (NTCs), e.g., amorphous and graphitic carbons, subsisting relative to a synthesized CNT layer are generally removed according to the present disclosure. NTCs are often formed when a catalyst for the production of CNTs is exhausted. Unlike CNTs, NTCs generally define porous structures which result in diffusion controllable trapping mechanisms. NTC coverage reduces a sorbent's overall accessibility to CNTs and slows down adsorption and desorption by introducing mass transfer limitations. Thus, purity of a synthesized CNT layer (marked by the absence of NTCs) may be a determining factor in the overall effectiveness of the CNT layer as a sorbent. In exemplary embodiments of the present disclosure, an oxidizing agent, e.g. air, oxygen and/or hydrogen peroxide, may be employed to facilitate the removal of NTCs.

In exemplary embodiments of the present disclosure, nanostructured iron (including CNTs and NTCs) is generated on an untreated stainless steel micro-capillary surface by oxidation-reduction reactions. CVD is employed using a carbon source flow of C₂H₄. NTCs generated are then selectively removed from the CNT layer by thermal oxidation or thermal annealing that is conducted in the presence of oxygen.

Exemplary embodiments of the apparatus, systems and methods herein disclosed present new and useful applications for CNTs, particularly for SWNTs, e.g., using nanosized carbon-based sorbents, e.g., CNTs, as the stationary phase of a chromatographic separation. More particularly, exemplary applications include the use of CNTs for the sorbent phase in a gas chromatography (GC) apparatus. Use of CNTs in sorbency applications, e.g., GC, presents significant improvements over prior art wherein thermal and mechanical stability (characteristic of CNT and particularly SWNT structures) is highly desirable. The use of CNTs in GC applications also results in improved resolution of the analytical separation (relative to prior art) due to nanoscale chemical interactions of CNTs with analytes. Furthermore, advantageous sorbency qualities are provided according to the present disclosure by use of CNTs in sorbency-related applications due to the relatively large surface areas and aspect ratios characteristic of CNTs.

Thus, an exemplary embodiment of the present disclosure relates to generation of SWNT-based, open, tubular columns for application as the stationary phase of a GC application. Self-assembled SWNTs are generated in long capillary tubing to serve as gas chromatography columns. The disclosed SWNT-based, open, tubular columns, fabricated via catalytic CVD inside silica-lined steel capillary columns may be advantageously used as the stationary phase for GC applications. In alternative embodiments of the present disclosure, MWNTs are deposited via CVD in a radially aligned configuration inside a capillary generating an effective gas chromatography column for analytical separations.

In other exemplary embodiments, the disclosed CVD process results in CNTs firmly anchored to the inner surface of the tubing. The densely packed and aligned layer of CNTs often grows vertically from the inside circumference of the tubing with a high degree of order. Under low temperature CVD conditions, the apparatus, systems and methods of the present disclosure exhibit varying inner and outer diameters of CNTs and an inner hollow core made of somewhat wavy MWNTs.

Preliminary tests demonstrate that the disclosed SWNT-based open tubular columns result in superior separation efficiency and high-resolution separations, while maintaining classical chromatography behavior. The large effective surface area of SWNT-based columns and high thermal stability facilitate/promote separation of higher molecular weights at higher temperatures, thus extending the range of SWNT-based chromatography applications beyond those of a conventional chromatography applications. SWNT-based chromatography applications according to the present disclosure are thus characterized by high-performance separation media through nanoscale interactions.

Additional advantageous features, functions and implementations of the disclosed systems and methods will be apparent from the description of exemplary embodiments which follows, particularly when read in conjunction with the appended figures.

### BRIEF DESCRIPTION OF THE DRAWINGS

To assist those of ordinary skill in the relevant art in making and using the subject matter hereof, reference is made to the appended drawings, wherein:

FIG. 1(a) depicts an exemplary setup for vapor-phase catalytic synthesis of SWNTs inside a metal capillary tubing.

FIG. 1(b) depicts variations in SWNT film thickness as a function of column length.

FIG. 2(a) and FIG. 2(b) depict SEM images of the surface of silica-lined tubing.

FIG. 2(a) depicts an SEM image of the surface of silica-lined tubing without pretreatment.

FIG. 2(b) depicts an SEM image of the surface of silica-lined tubing with pretreatment, wherein water was sprayed at 725° C.

FIG. 3(a) depicts an RBM spectra of SWNTs synthesized at 725° C.

FIG. 3(b) depicts a Raman spectra of D and G signals of synthesized SWNTs.

FIG. 3(c) and FIG. 3(d) depict SEM images of an SWNT film on a metal capillary tubing.

FIG. 4(a), FIG. 4(b), FIG. 4(c), FIG. 4(d) and FIG. 4(e) depict chromatograms generated from a SWNT column. In particular, FIG. 4(a) depicts the ppm level of alkane standard at conditions of 30° C. for 0.5 min, at 40° C./min to 250° C., a flow rate of carrier gas 1.5 mL/min and 20-iL injection; FIG. 4(b) depicts high molecular weight n-alkanes at conditions of 120° C. for 0.1 min, at 40° C./min to 425° C., 5 min, and a flow rate of carrier gas 5.0 mL/min; FIG. 4(c) depicts the separation of deuterated PAH mixture, 0.6 iL, 1:20 split ratio where the conditions included an oven temperature of 125° C., at 30° C./min to 425° C., 10 min and 300° C. injector, detector; FIG. 4(d) depicts the separation of alcohols, where the conditions were 120° C. for 0.5 min, 40° C./min to 250° C. with a flow rate of carrier gas at 5.7 mL/min; and FIG. 4(e) is a chromatogram illustrating the column bleed test showing a stable baseline, where conditions were 30° C. for 2 min, at 30° C./min to 425° C., 4 min.

FIG. 5 depicts a Van Deemter plot for ethylbenzene. (Hmin: 0.42 cm at 3.5 mL/min).

FIG. 6 depicts Van't Hoff plots (variation in capacity factor with temperature) for hexane and benzene (dotted plot).

FIG. 7(a) depicts a schematic diagram of CVD set up.

FIG. 7(b) depicts a schematic of an exemplary gas chromatography setup for evaluation of the columns, wherein gas samples are injected using a tenport gas sampling valve.

FIG. 8(a), FIG. 8(b), FIG. 8(c), FIG. 8(d), and FIG. 8(e) depict SEM images of CNT self-assembly. In particular, FIG. 8(a) depicts nanostructured iron on a tube surface after surface treatment; FIG. 8(b) depicts CNTs covered with amorphous carbon from CO—CVD, before oxidative annealing; FIG. 8(c) depicts CNTs from CO—CVD after oxidative annealing; FIG. 8(d) depicts CNTs covered with amorphous carbon from C₂H₄—CVD, before oxidative annealing; and FIG. 8(e) depicts CNTs from C₂H₄—CVD after oxidative annealing.

FIG. 9 depicts variation in film thickness (microns) as a function of length, wherein a column was formed by CVD using C₂H₄ as a precursor and a deposition time of 1 hour.

FIG. 10(a), and FIG. 10(b) depict typical chromatograms generated from the CNT column in FIG. 9. In particular, FIG. 10(a) depicts a chromatogram generated from a large volume injection of 5 ml (temperature program from 30° C. to 325° C. at 50° C./min, flow rate was 10 ml/min.). Large volume injection was employed for the ppb level standard used in this analysis. FIG. 10(b) depicts a chromatogram generated from a 10 microliter injection of a ppm level standard (temperature program from 30° C. to 300° C. at 70° C./min, flow rate was 7 ml/min).

FIG. 11 depicts the height equivalent of theoretical plates as a function of flow rate for methane at 30° C., and ethylene at 120° C.

FIG. 12 depicts a Van't Hoff's plot of variation in capacity factor with temperature for methane and ethylene.

FIG. 13 depicts a schematic of an exemplary CVD setup wherein a coiled metal tubing is included.

FIG. 14(a) depicts an SEM image of a cross section of stainless steel tubing showing a layer of the CNT coating.

FIG. 14(b) depicts an SEM image of vertically aligned CNTs on a steel tubing surface.

FIG. 15(a) and FIG. 15(b) depict TEM images of CNTs removed from the inside of the steel tubing in FIG. 14(a) and FIG. 14(b).

FIG. 15(a) depicts a TEM image of individual CNTs containing the catalyst particles.

FIG. 15(b) depicts a TEM image of CNTs that may be produced using the herein disclosed apparatus, systems, and methods.

FIG. 16(a), FIG. 16(b) and FIG. 16 (c) depict SEM images of a stainless steel surface showing granular structures resulting from surface conditioning. In particular, FIG. 16(a) depicts a steel surface conditioned at 500° C.; FIG. 16(b) depicts a steel surface conditioned at 700° C.; and FIG. 16(c) depicts exemplary CNT growth on surface conditioned at 500° C.

FIG. 16(d) depicts exemplary CNT growth on surface conditioned at 700° C.

FIG. 17(a), FIG. 17(b), FIG. 17(c), and FIG. 17(d), depict SEM images illustrating variation in uniformity of a CVD coating along the length of a steel tubing. In particular, FIG. 17(a) depicts the CVD coating 20 cm from the entrance of the steel tubing, wherein the steel tubing was conditioned at 500° C.; FIG. 17(b) depicts the CVD coating 40 cm from the entrance of the steal tubing, wherein the steel tubing was conditioned at 500° C.;

FIG. 17(c) depicts the CVD coating 20 cm from the entrance of the steel tubing, wherein the steel tubing was conditioned at 700° C.; and FIG. 17(d) depicts the CVD coating 40 cm from the entrance of the steal tubing, wherein the steel tubing was conditioned at 700° C.

FIG. 18 depicts the thickness of a CNT and amorphous carbon coating along the length of a stainless steel tubing, wherein CVD duration was varied from 1 to 15 min. at a constant ethylene flow rate of 20 sccm.

FIG. 19 depicts the thickness of CVD coating along the length of steel tubing as a function of flow rate for a constant CVD time of 15 min.

FIG. 20(a) and FIG. 20(b) depict SEM images of a CVD coating subjected to oxidation, wherein the CVD coated structure was heated in the presence of oxygen at 375° C. to selectively burn off the amorphous carbon layer. In particular, FIG. 20(a) depicts the CVD coated structure before oxidation; and FIG. 20(b) depicts the CVD coated structure after oxidation.

FIG. 21 is a schematic diagram of an experimental system used for data acquisition according to the present disclosure.

FIGS. 22(a) to FIG. 22(e) are SEM images of test samples described herein.

FIG. 23 is a plot of detector response as a function of injection interval for an exemplary SWNT microtrap.

FIG. 24 is a plot of detector response as a function of injection interval for toluene, using microtraps containing different sorbents.

FIG. 25 is a plot of breakthrough time as a function of temperature (1/T) for benzene.

FIG. 26 is a plot of desorption profile of toluene with different sorbents within a microtrap.

### DESCRIPTION OF EXEMPLARY EMBODIMENTS

Apparatus, systems and methods for the production and application of carbon nanotubes (CNTs) are provided according to the present disclosure.

Exemplary embodiments of the present disclosure relate to gas chromatography separations in an open tubular format using self-assembled single walled carbon nanotubes (SWNTs) inside silica-lined steel capillary tubing. The SWNT layer is generally self-assembled by a unique single-step, catalytic chemical vapor deposition (CVD) process, e.g., employing dissolved cobalt and molybdenum salts (i.e., the catalysts) in ethanol (i.e., the precursor).

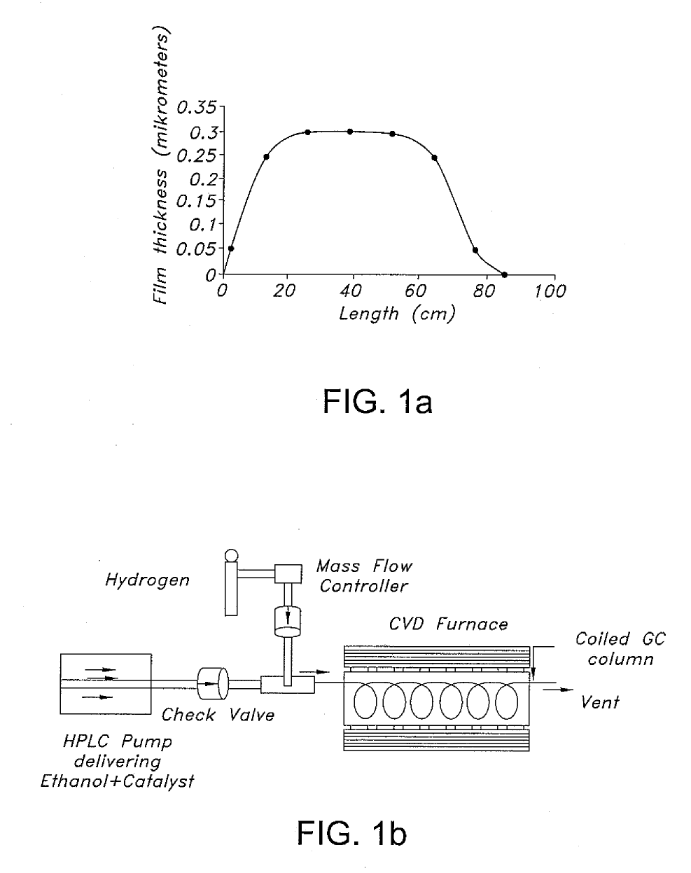

In exemplary embodiments, a separation column is prepared by dissolving cobalt nitrate hexahydrate, Co(NO₃)₂.6H₂O and molybdenum acetate, (CH₃COOH)₂Mo in ethanol at 0.2 wt % and 0.05 wt % concentrations, respectively. The dissolution process may be assisted by sonication. An exemplary CVD system for use according to the present disclosure is depicted in FIG. 1. The ethanolic solution containing the catalyst in the dissolved form is injected into the capillary metal tubing using an HPLC pump. A typical flow rate is 100 μL/min. Hydrogen is simultaneously introduced into the tubing through a three-way connector; a typical hydrogen flow rate is 40 cm³/min. Check valves are placed on both lines to restrict backflow. CVD is performed, e.g., for approximately 12 minutes.

Various substrates, such as 304- and 316-type stainless steel capillary tubing; silica-lined metal capillary tubings, such as Silcosteel™ and Sulfinert™ tubes, can be used according to the present disclosure for self-assembly of SWNTs. In exemplary embodiments of the present disclosure, substrate tubes are washed with ethanol prior to CVD to remove any particles/impurities. Dimensions of tubes may vary from application to application. For example, an exemplary tubes processed according to the present disclosure may be approximately 1 meter in length and define an internal diameter (ID) of about 0.5 mm (e.g., 0.53 mm). After CVD processing and prior to GC use, the resultant CNT layered columns are generally subjected to an oxidation step, e.g., by treatment at about 200° C. in air for 1 hour to oxidize non-tubular carbons (NTCs). Oxidation may be effective to address amorphous carbon and other impurities generated during the CVD process (or otherwise present). Further impurity removal may be undertaken, e.g., by heating the column in an inert atmosphere (e.g., argon) at 425° C. for 1 hour to remove any low-boiling impurities.

A SWNT film produced according to the present disclosure can be characterized by Raman spectroscopy performed at 632.8-nm excitation. To study the CNT formation according to the present disclosure, segments of 1-cm length were cut from a CNT layered steel tube at five equidistant locations. The samples were cut so as expose the inside surface and analyzed by a field emission scanning electron microscope. The distribution, surface coverage and thickness of the SWNT coating were studied on the basis of the SEM images. In this case, a gas chromatograph with a flame ionization detector (FID) was used to study analyte separations. Gas samples are injected using an electronically controlled 10-port sampling valve with injector and detector temperatures at 250° C. Liquid injections were made manually using an injection port with injector and detector temperatures at 280° C. Helium was used as the carrier gas.

In this particular embodiment, silica-lined Sulfinert™ stainless steel tubing was used as the substrate for the CVD process. In previous studies, the role of iron in the steel tubings as a catalyst for formation of nanotubes led to MWNT formation, rather than the more desired SWNT formation. In general, a strategy for selective SWNT growth may involve prevention of iron in the bulk steel from participating in the process.

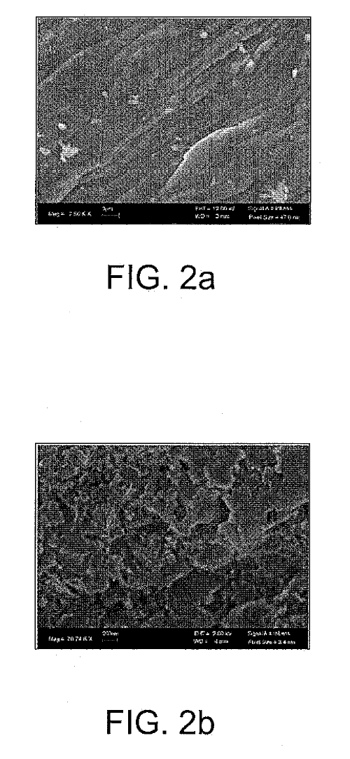

SEM images of the noted stainless steel tubing samples (FIG. 2) show that during high-temperature CVD, a silica coating developed microscale cracks, thus increasing the surface area and roughness, thereby providing sites for catalyst deposition. The nanostructured metal catalyst was generated in situ during the CVD process. The catalyst precursor metal complex was dissolved in ethanol, and the solution in conjunction with the flowing hydrogen created an ethanol-catalyst aerosol inside the tube. At high temperature (725° C.), the solution vaporized and distributed the catalyst along the entire length of the tube. The CoNO₃ broke down to form Co nanoparticles that were activated in the reducing H₂ environment. The metal then catalyzed SWNT growth, while the alcohol served as a carbon source.

The SEM images of the silica-lined tube sections along the length of the tube reveal a randomly aligned layer of thin SWNT film occasionally interspersed with little MWNTs and amorphous carbon. The surface coverage along the length varied, with the midsection having a higher density of relatively constant thickness. The variation in film thickness along the length of the column for this embodiments is presented in FIG. 1b. The drop in film thickness at the ends may be due to the relatively cooler temperatures at the ends as compared to temperatures at the midsections. According to the present disclosure, film thickness can be varied by altering CVD conditions.

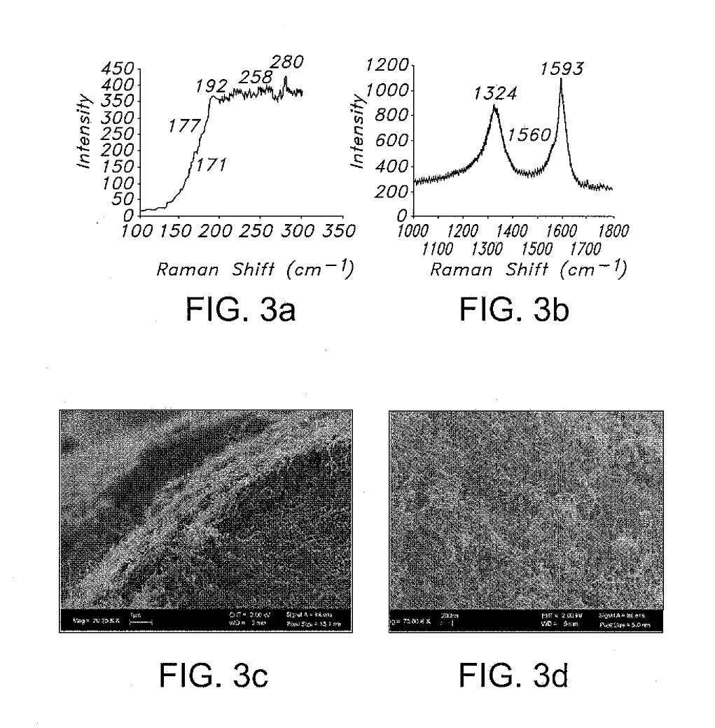

The presence of SWNTs can be confirmed by Raman spectroscopy on all of sections of the tubing. Multiple tubes are generally analyzed to check for reproducibility. Exemplary Raman spectra for the noted samples are shown in FIG. 3(a) and FIG. 3(b). These spectra depict the presence of a radial breathing mode (RBM), which is a characteristic of SWNTs. On the basis of characteristic peaks at wave numbers of 190, 217, 221, 248 and 287 cm⁻¹, the SWNT diameters are calculated to be between 0.87 and 1.3 nm.

In this disclosed embodiment, the SWNT film was morphologically different from previously reported MWNT films. Indeed, the MWNTs of the present disclosure were vertically aligned with the tubes, forming a forest-like structure. The density could be relatively high based on the CVD conditions/processing parameters employed. In the case of the SWNTs, the tubes did not have any preferential alignment and formed noodle-like structures. The tube density was significantly smaller than the MWNTs, as shown in FIG. 3(d). Thus, the SWNT and MWNT based stationary phases are expected to be functionally different.

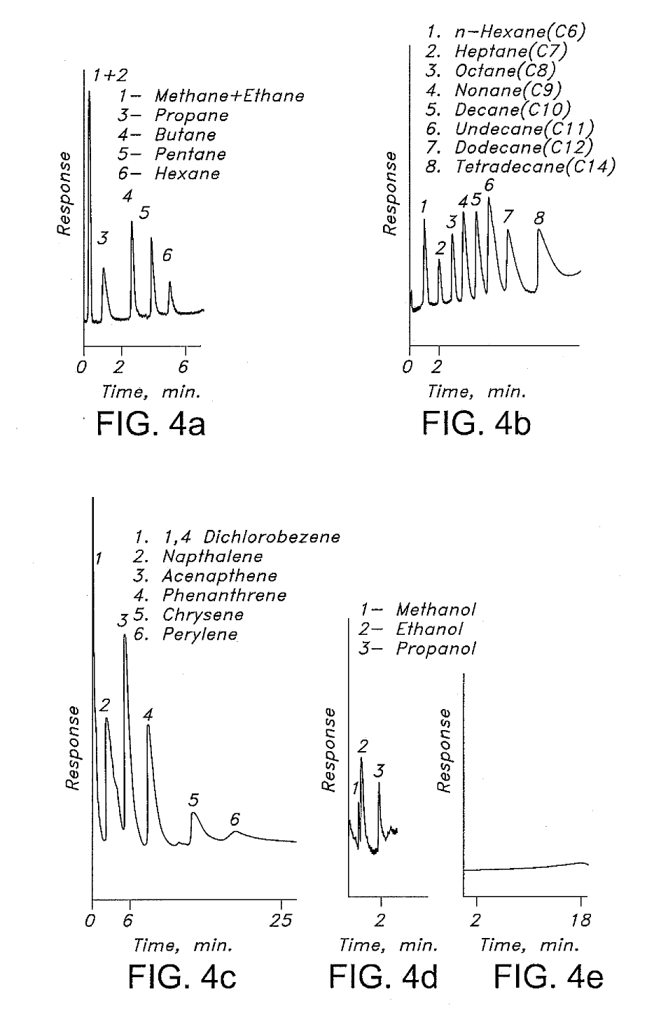

A wide range of organic compounds can be separated on columns produced according to the present disclosure. In an exemplary embodiment, the separation of molecules with lower molecular weights, e.g., C₁-C₆ alkanes, is shown in FIG. 4(a), and the separation of molecules with larger molecular weights, e.g., C₆-C₁₄, and a polyaromatic hydrocarbon (PAH) mixture, are shown in FIG. 4(b) and FIG. 4(c), respectively. Normally, separation of lower molecular weight hydrocarbons would be carried out in a packed GC column, and an open tubular column would be suitable for higher molecular weight/PAH systems. The use of SWNT-based columns as the stationary phase in GC, however, allows both of these separations to be carried out in an open tubular format at high resolution. Although methane and ethane were not separated in the noted tests, a longer length column and/or sub-ambient cooling could be used to separate methane and ethane. The ability to use an SWNT based stationary phase in the separation of analytes with a wide range of boiling points and volatility is highly advantageous for GC purposes, especially given the inherent stability of SWNT structures at high temperatures.

An SWNT-based column can also be used for a variety of other separations, e.g., separation of halohydrocarbons, alcohols, ketones and alkane isomers. The chromatogram in FIG. 4(d) depicts an exemplary separation of alcohols according to the present disclosure. The baseline from heating an SWNT column to 425° C. is depicted in FIG. 4(e). The reported data shows no column bleed or other instability at higher temperatures. Of note, the analytes chrysene and perylene in the PAH mixture as well as dodecane and tetradecane in the n-alkanes mixture (FIG. 4(b) and FIG. 4(c)) eluted at temperatures around 425° C. with nearly symmetrical peaks. Typical reproducibility in retention time measured as relative standard deviation (RSD) was <2%, which is comparable to results for commercial GC columns. Band-broadening and column efficiency were obtained from plate theory of chromatography.

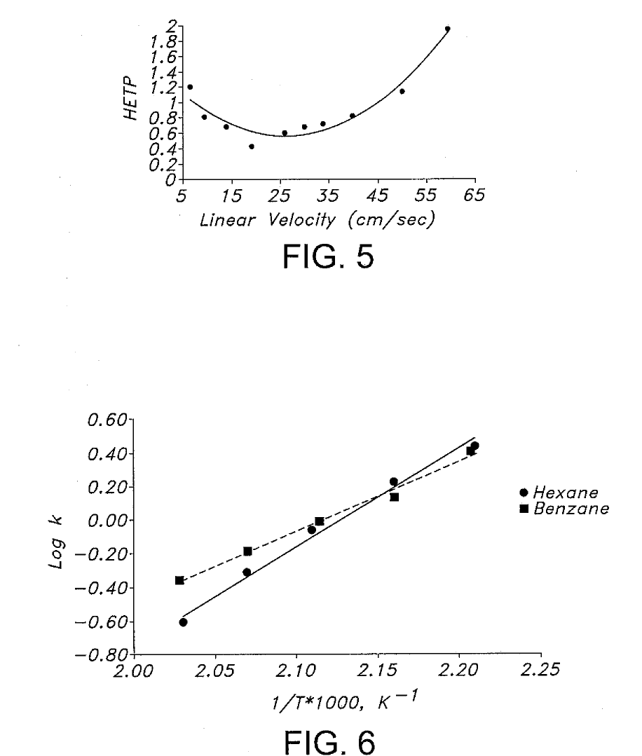

Typical chromatographic efficiencies for the exemplary column of FIG. 4 are presented in Table 1 (below). The number of theoretical plates (N) obtained on the SWNT film for a 0.75-m length tube are comparable to the conventional open tubular columns. FIG. 5 shows the Van Deemter plot for the column with ethylbenzene at 200° C. The minimum height equivalent theoretical plate (HETP) is 0.42 cm, and the optimum flow rate of the carrier gas ranged between 3.5 and 4.5 mL/min, which is typical for columns of this type with this internal diameter. FIG. 6 shows the Van't Hoff plot with the dependence of log k′vs reciprocal temperature for n-hexane as well as benzene. The linear plot (with correlation coefficients of 0.99) suggests that the separation follows classical chromatographic behavior.

TABLE 1
Column efficiency data

| | Column | Capacity | Temp. |
|---|---|---|---|
| Solute | efficiency (N) | Factor (k′) | (° C.) |
| Pentane | 759 | 3.270 | 130 |
| Dichloromethane | 745 | 4.486 | 50 |
| Toluene | 785 | 7.283 | 200 |
| O-Xylene | 793 | 10.962 | 240 |
| Ethylbenzene | 689 | 6.216 | 230 |
| Nonane | 625 | 13.915 | 270 |

Retention on the SWNT film was compared to that on a column packed with a commercial carbon phase, such as a Carbopack C™ column. Table 2 (below) presents capacity factors of a few representative analytes on SWNT column versus a Carbopack C column. The capacity factors are usually proportional to the mass and surface areas of the sorbent material. Table 2 suggests that the capacity factors obtained on the 200-300 nm thick SWNT phase are comparable to a packed column containing 0.352 g of the sorbent material. The specific surface area of the Carbopack C column was approximately 10 m²/g. The high capacity factor on such a thin film reflects the high surface area of the SWNT phase.

TABLE 2
Comparison of capacity factors (k′) on SWNT column
and packed Carbopack C ™ column

| Sample | SWNT-k′ | Carbopack-k′ | Temp. |
|---|---|---|---|
| Hexane | 3.390 | 4.005 | 180 |
| Benzene | 3.125 | 2.562 | 180 |
| Methylethylketone | 0.531 | 1.500 | 180 |
| Chloroform | 3.450 | 3.048 | 100 |
| Propane | 1.508 | 1.625 | 30 |

Table 3 (below) presents the isosteric heats of adsorption (ΔHₛ) in the infinite dilution region for selected analytes on the SWNT column of the present disclosure and the packed Carbopack C column over a temperature range of 443-493° K. The ΔHₛ values for the adsorption of organic vapors were calculated from the retention volumes (plot of ln(VN)/T against 1/T, where the slope is −ΔHₛ/R). The regression coefficients were approximately 0.99 for all plots. The isosteric heat of adsorption characterizes the activation energy for sorption and, consequently, is a measure of sorbate-sorbent interaction. The data suggests stronger interaction of organic vapors with the disclosed SWNT sorbent relative to the Carbopack C column. The trend of ΔHₛ of adsorption for the SWNT phase is hexane>benzene>methyl ethyl ketone, opposite to that of their dipole moments and capacity factors (k′). This trend is similar to that observed by Agnihotri et al. in their estimation of ΔHₛ for these organic vapors from a gravimetric approach. [See, Agnihotri, S.; Rood, M. J.; Rostam-Abadi, M. J. Mat. Res. 2005, 43, 2379-2388.]

TABLE 3
Isosteric heats of adsorption (ΔHₛ) on SWNT column
and packed Carbopack C ™ column

| | SWNT-ΔHₛ | Carbopack-C-ΔHₛ |
|---|---|---|
| Sample | (kJ · mol⁻¹) | (kJ · mol⁻¹) |
| Hexane | 59.53 | 19.18 |
| Benzene | 55.88 | 16.0 |
| Methyl ethyl ketone | 39.12 | 14.88 |

Polarity of the SWNT stationary phase was evaluated by calculating the McReynolds constants (ΔI) at 120° C. The data presented in Table 4 (below) suggests that the SWNT phase is nonpolar. Benzene showed a negative ΔI value, which implies hexane adsorbed more strongly than benzene. This is also observed from the ΔHₛ of adsorption and the capacity factors. This property of CNTs was reported previously by Bittner et al. during their study on the characterization of the surfaces of SWNTs by a pulse adsorption technique. [See, Bittner, E. W.; Smith, M. R.; Bockrath, B. C. Carbon 2003, 41, 1231-1239.] In particular, Bittner et al. observed that hexane is the most strongly held among other organic compounds, such as benzene, ethanol and 2-propanol. Therefore, with respect to benzene, the SWNT phase is more nonpolar than squalane. Elution sequences of the McReynolds probes were benzene, 1-butanol, 2-pentanone, and pyridine, respectively.

TABLE 4
McReynolds Constants for SWNT column

| | | 1- | 2- | 1- | |
|---|---|---|---|---|---|
| Probe | benzene | butanol | pentanone | nitropropane | pyridine |
| I for SWNT | 589.7 | 689.5 | 752.2 | — | 874.9 |
| I for Squalane | 653 | 590 | 627 | 652 | 699 |
| ΔI | −63 (x′) | 100 (y′) | 125 (z′) | (u′) | 176 (s′) |

To evaluate column-to-column reproducibility, three SWNT columns were prepared under identical conditions, and the capacity factors obtained for selected solutes (see Table 5 below). The low RSD values demonstrate that the disclosed CVD process used for SWNT deposition is a reliable and reproducible technique.

TABLE 5
Evaluation of Capacity factors for column-column reproducibility.

| | Ethylbenzene | Nonane |
|---|---|---|
| | Capacity | Capacity |
| Column | Factor (k′) | Factor (k′) |
| 1 | 10.423 | 8.690 |
| 2 | 10.269 | 8.653 |
| 3 | 10.216 | 8.480 |
| | RSD (%) 1.04 | RSD (%) 1.3 |

As demonstrated herein, SWNT-based open tubes for application in the stationary phase of GC may be fabricated via the disclosed catalytic CVD process within silica-lined steel capillary columns. The disclosed SWNT-based columns demonstrated advantageous separation efficiency, classical chromatography behavior and facilitated high-resolution separations. The high surface area of the SWNT phase allows for the separations of gases, while the excellent thermal stability permits separations of higher molecular weights at higher temperatures, thus extending the range of conventional chromatography on the same column. SWNTs thus function as high-performance separation media through nanoscale interactions.

In a further exemplary embodiment of the present disclosure, self-assembled CNTs are generated in long capillary tubing to serve as gas chromatography columns. CNTs are deposited as a film by CVD over long lengths of the tubing to form effective stationary phases in the open tubular format for gas and liquid chromatography columns for analytical separations.

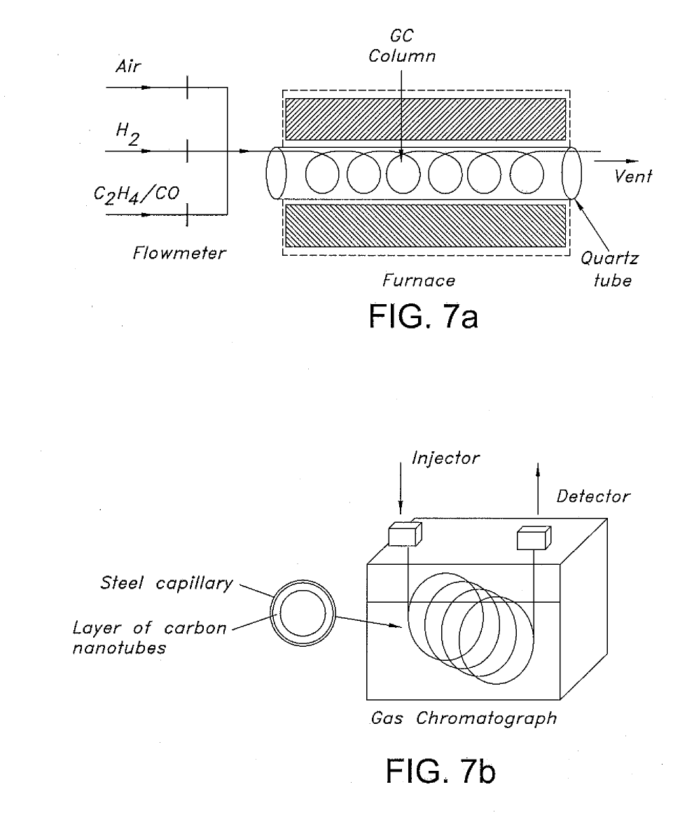

In this exemplary embodiment, self-assembly of CNTs in 500 μm ID capillaries was carried out in a tube furnace by the CVD method, as described, e.g., by Saridara et al. [Saridara, C., Brukh, R., Iqbal, Z., and Mitra, S. Anal. Chem., 2005, 77(4) 1183-1187] and Sharma et al. [R. Sharma, Z. Iqbal, Appl. Phys. Lett. 2004, 84, 990-992.] The foregoing publications are herein incorporated by reference. However, the previously described techniques are modified according to the present disclosure for growth in long tubes, as shown in FIG. 7. A variety of carbon sources including CO, CH₄, ethanol and C₂H₄ have been evaluated for CVD of a uniform CNT layer. Ethylene was found to consistently provide high density/uniform films that are useful for GC separation, although the present disclosure is not limited to ethylene-based applications.

Depositing a uniform catalyst layer on the inside surface of a long capillary tubing can be relatively difficult. Two types of micro-capillaries have been evaluated, namely (i) silica-lined stainless steel and (ii) untreated stainless steel. Preliminary attempts with the silica-lined tubing showed non-uniform and often sparse CNT growth as compared with the robust growth observed for untreated stainless steel tubes. The observed growth differential may be due to formation of nanocrystals of iron on the untreated stainless steel surfaces, which catalyzed growth of CNTs.

Surface treatment is generally needed and/or advantageous to enhance catalytic activity of the iron in the steel tubing. In the absence of such surface treatment, amorphous carbon was formed during the CVD process. An exemplary surface treatment to generate nanostructured iron on a steel tube surface according to the present disclosure involved the following: the capillary is heat-treated in air at 500° C. for 30 min to oxidize the surface, and then the surface is reduced in a flow of H₂ at 500° C. for 30 min.

The disclosed oxidation-reduction process leads to the formation of a catalytically active tubing surface. In an exemplary embodiment of the present disclosure, after the oxidation reduction process, CVD was carried out in a flow of C₂H₄ at 700° C. for between 1 to 3 hours. This process formed a GC column with a thin-film of CNTs along with amorphous carbons and other NTCs. NTCs were then removed via thermal oxidation in the presence of oxygen at 350° C. Inclusion of the thermal oxidative step selectively removes the carbonaceous layer while leaving the nanotubes intact. Depending upon the CVD conditions, the synthesized nanotube layer may range in thickness from 1 to 50 microns. The thickness of the CNT film may be measured by cutting the column at different points and making measurements using SEM technology. Thereafter, chromatographic separations using synthesized GC columns may be carried out, e.g., using a GC with a flame ionization detector. GC injections may be made, e.g., with a Valco gas sampling valve.

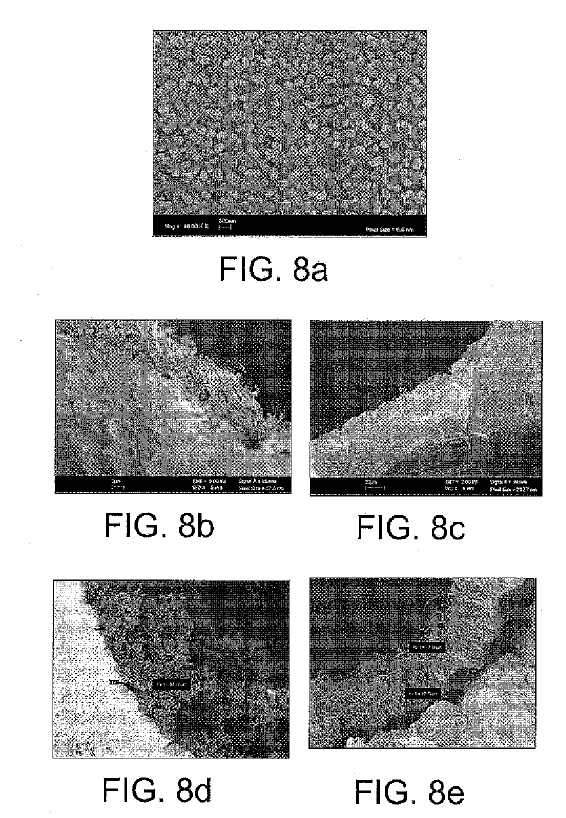

In an exemplary embodiment of the present disclosure, oxidation-reduction processing of the steel tubing led to formation of nano-structured iron crystals on the steel tubing as shown in FIG. 8a. CVD with C₂H₄ as a precursor formed a thin CNT film (micron scale) along with some non-nanotubular carbonaceous material on top. The CNT film was anchored to the metal surface, while the non-nanotubular carbonaceous material generally defined a layer of loose particles. CNTs have significantly higher thermal stability than the amorphous and other non-tubular carbons. Thus, the amorphous/non-tubular carbons can be selectively removed by thermal annealing in presence of oxygen while leaving the nanotubes intact. The removal of NTCs via thermal annealing is presented in the SEM images of FIG. 8(d) and FIG. 8(e). In FIG. 8(e), an amorphous carbon layer has been removed, effectively exposing the CNT layer, e.g., for adsorption during chromatographic separation.

Similarly advantageous results were obtained according to the present disclosure for CO CVD of CNTs; however, as can be seen in FIG. 8(c), the CNT layer synthesized using CO as the carbon source was sparse as compared to CVD using C₂H₄ as the carbon source. CNTs deposited using the above described process are MWNT which are radially aligned inside the tube. Raman spectra taken from the inside surface of a cut capillary did not show characteristic peaks typically associated with the strongly diameter-dependent radial breathing mode of SWNTs below 300 cm⁻¹, which suggested that SWNTs are not formed under the prevailing conditions. Changing the CVD precursor and the deposition conditions could vary the thickness of the CNT films grown in the capillary. The thickness of the CNT layer is an important parameter in determining the sorption capacity and mass transfer rate of a given column. The ability to predetermine thickness and thus predetermine sorption capacity, ultimately allows for fabrication of different types of columns for diverse applications.

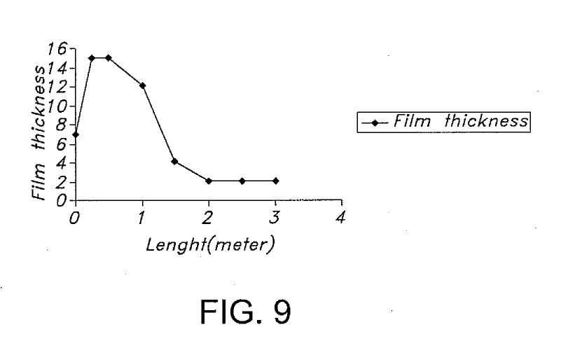

In developing a relatively uniform film of CNTs, it is noted that the CVD process is strongly dependent upon the residence time of free radicals generated during the flow of precursors. Consequently, CNT deposition and film thickness may be varied along the length of a long column by varying process parameters. Typical variations are shown in FIG. 9. In this particular case, only the first 1.2 m of the column served as an effective stationary phase for GC separation. By varying flow conditions and CVD precursors, film thickness and morphology of the deposited CNT may be altered, thus affecting sorption capacity. For example, under similar conditions, CO and C₂H₄ precursors generated CNT layers with significantly different diameters and densities.

Generally, a CNT film yields an excellent chromatography stationary phase and can be used as an effective separation media. CNT films are stable and can handle temperature cycling associated with typical GC applications. To this end, the same synthesized GC column can be used for months. Typically, there is no column bleed and the base lines are stable. A wide range of organic molecules may be separated on the disclosed CNT-based columns.

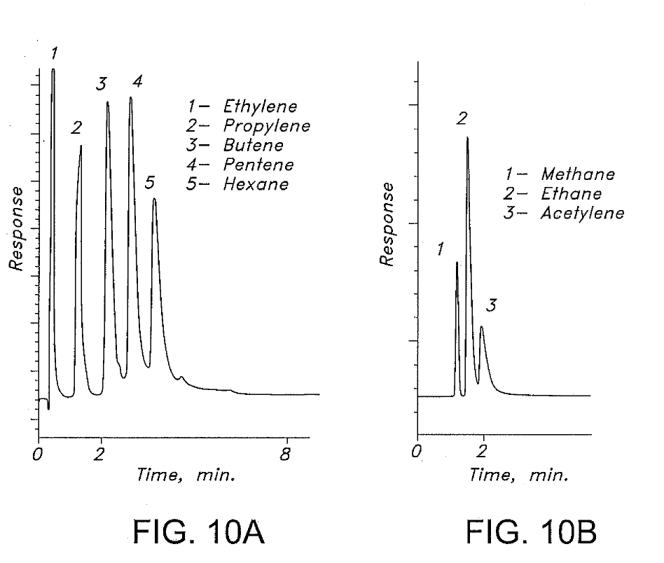

An exemplary separation of a group of alkenes is shown in FIG. 10. Given the highly volatile compounds used, the separation depicted would normally have been carried out in packed GC columns. The application of a CNT layer allows the same separation to be carried out in an open tubular format, resulting in significantly higher resolution. The same column can also be used in the separation of relatively less volatile compounds, such as benzene and toluene. A particular advantage of the disclosed CNTs is their inherent stability at high temperatures. Temperature stability is particularly important from the standpoint of GC, because it can greatly increase the range of separable compounds.

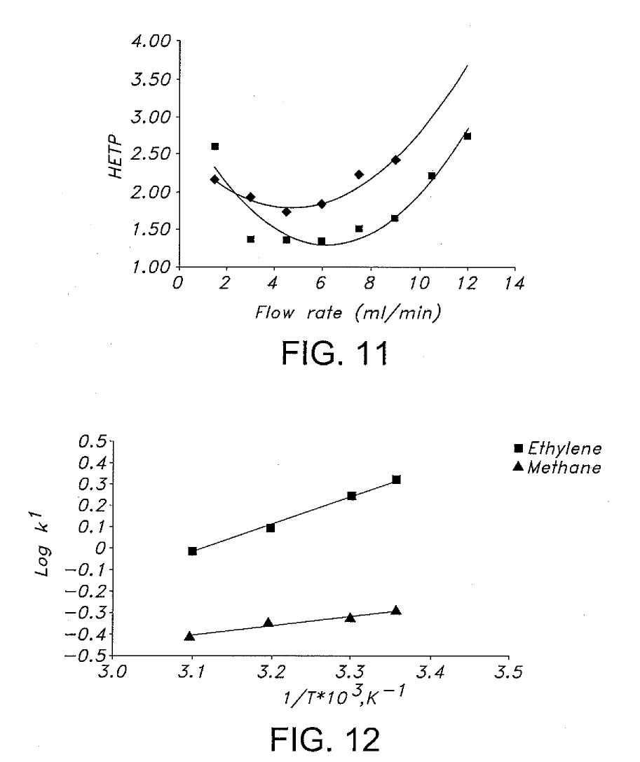

The disclosed CNT films exhibit classical chromatographic behavior. Accordingly, the efficiency of separation can be estimated using the plate theory of chromatography. The height equivalent of a theoretical plate (H) varies as a function of flow rate. Typically, the minimum height equivalent correlates to an optimum flow rate for separation. Variations of H with flow rate are presented for methane and ethylene in FIG. 11. Similar results are obtained for several other compounds. For the presented cases, optimum flow rates range from 4 to 8 ml/min, which is typical of open tubular columns with the noted internal diameters. The separation capability of a GC column is computed based on the number of theoretical plates. In exemplary embodiments, the plates per meter at optimum flow rate (based on FIG. 11) were found to be 1500 and 1940 for ethylene and methane, respectively. The retention as measured by capacity factor generally decreases with temperature, while also following classical chromatographic behavior. The logarithm of k′ varied linearly with the reciprocal of temperature. The variance is shown in FIG. 12.

Thus, in exemplary embodiments of the present disclosure, CNT-based open-tubular GC stationary phases are advantageously fabricated via CVD on steel capillaries. This phase typically demonstrates classical chromatography behavior and high resolution. A major advantage is the ease of fabrication by the self-assembly of CNTs directly on the tube surface. The nanostructured metal catalyst developed on the tube surface effectively anchors the CNTs, leading to the formation of a stable stationary phase. The high thermal stability of CNTs allows for separations at higher temperatures, extending the range beyond conventional chromatography. The thickness of the CNT film and its morphology can be tailor-made by varying several parameters, including, inter alia, the CVD precursor, CVD catalyst, substrate surface, method of catalyst preparation, and the like. The thickness of the CNT film and its morphology can also be controlled via chemical functionalization. Ultimately the ability to control CNT film thickness and morphology enables the development of a wide range of chromatographic columns with variable selectivity.

In further exemplary embodiments of the present disclosure, scaled-up self-assembly of CNTs on the inside wall of relatively long stainless steel tubings for potential large scale applications, such as separations and chromatography, has been undertaken. Thus, CNTs have been deposited by chemical vapor deposition (CVD) using ethylene as the carbon source, while the iron nanostructures in the stainless steel serve as catalysts. As in the previously disclosed embodiments, the coating that is formed on the internal surface of the steel tubing typically contains a layer of CNTs aligned perpendicular to the tube circumference and a layer/overcoat of disordered carbonaceous material. The overcoat layer may be selectively oxidized by annealing in oxygen, thus exposing the underlying CNT layer.

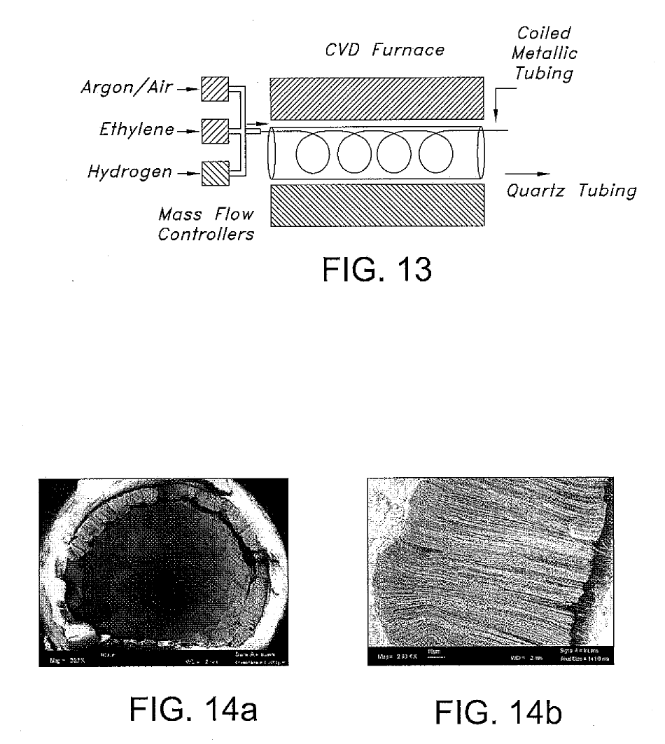

In exemplary “scale-up” embodiments of the present disclosure, a type 316 grade stainless steel tubing (2 ft long, 1/16″ OD and 1.27 mm ID) was used as substrate for CNT deposition. The tubing was coiled and placed in a quartz tube (located in a 40 cm long horizontal CVD furnace as shown in FIG. 13). Though a 2 ft length of tubing was subjected to CVD processing, an effective length of about 40 cm was subjected to the high temperatures described herein. One end of the tubing was connected to the gas flow. The flow rate of the precursor inside the metal tubing was controlled by flow meters which were positioned before the metal tubing.

In the disclosed embodiment, the self-assembly process generally included three steps: (1) the surface of tubing was oxidized at 500° C. or 700° C. for 45 mins by flowing air at 65 standard cubic centimeters (sccm); (2) the surface was reduced with hydrogen at 500° C. or 700° C. for 45 mins at the same flow rate; and (3) CVD was carried out at an ethylene flow rate of 5 to 20 sccm, at 700° C. for 1 to 60 mins. The tubing was then allowed to cool to room temperature in an argon environment (in order to prevent oxidation during this cool-down period). Alternatively, the tubing may be allowed to cool to the specific temperatures used in an oxidative thermal annealing step, whereby NTCs are removed in the presence of oxygen, e.g., at a flow rate of 50 sccm.

Six tubing samples fabricated according to the disclosed self-assembly process were tested. Each sample was 1 cm in length and was cut out from a different location at equal distances from the tubing inlet. The first sample—which was subjected to CVD in the hot zone of the furnace—was obtained at a location about 1-2 cms from the inlet end of the tubing. The subsequent five samples were cut at intervals of about 10 cm. The samples were then cut open to expose the inside surface and analyzed by field emission-scanning electron microscope. Selected samples were also examined by transmission electron microscopy (TEM).

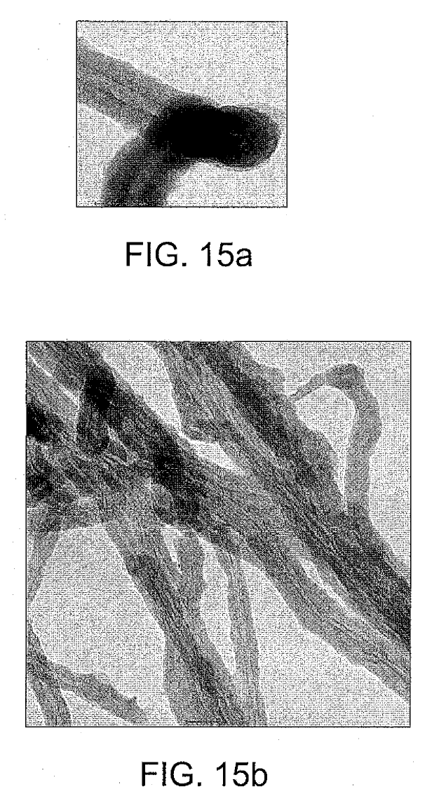

Consistent with the advantageous results described above, the “scaled-up” CVD process was effective in synthesizing CNTs that were firmly anchored to the inner surface of the tubing. SEM images revealed a layer of CNTs that are densely packed and aligned, often growing vertically from the inside circumference of the tubing. FIG. 14(a) and FIG. 14(b) show a cross section of the tubing containing the self assembled CNTs. FIG. 15 shows TEM images of the CNTs collected from inside the steel tubing. The images reveal the relatively high degree of order of the graphitic structure along the CNT walls, varying inner and outer diameters of CNTs, and an inner hollow core characteristic of somewhat wavy MWNTs that are typically formed in low temperature CVD conditions. The catalyst particle enclosed inside the CNT tip is also revealed at higher magnifications.

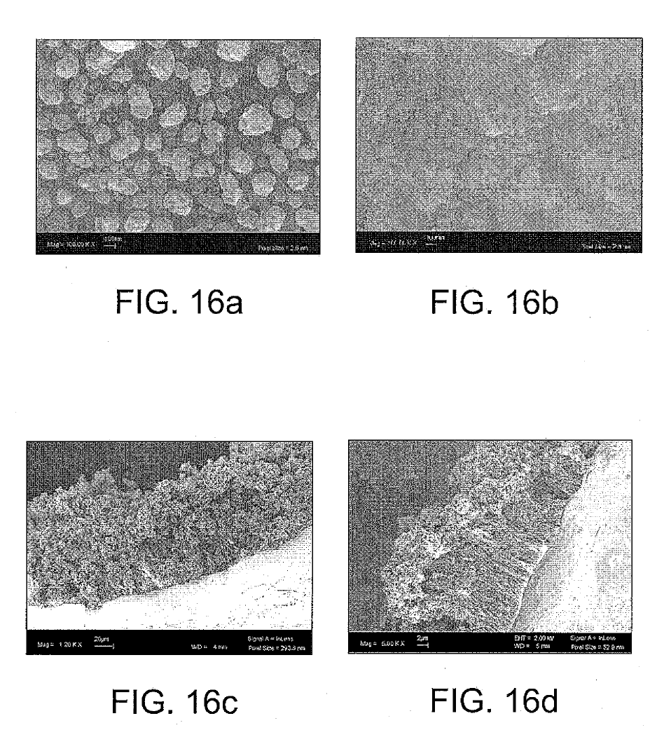

Conditioning of the metallic surface prior to the CVD process is important for two reasons. First, surface conditioning result in enhancing/toning the metal surface for its latent catalytic activity by forming nano-scale granular structures. Secondly, the surface becomes structurally (microscopically) more homogenous, which is important for the uniform growth of nanotubes. In exemplary embodiments of the present disclosure, the surface conditioning is performed in two stages: (1) oxidation of the metallic surface by airflow at elevated temperatures followed by (2) subsequent reduction by the flow of hydrogen. Oxidation by a flow of air results in the breakup of the metallic surface to form fine granular structures, as seen in the SEM images of FIG. 16(a) and FIG. 16(b). The increased surface area and granular structures promoted by surface conditioning enhance catalytic activity. The efficacy of the oxidation-reduction pretreatment prior to CVD growth of CNT has been discussed by Vander Wal et al. [See, Wal, R L V, Hall, L J. Carbon nanotube synthesis upon stainless steel meshes. Carbon 2003; 41: 659-672.]

Temperature generally plays an important role in the surface conditioning process. In testing conducted according to the present disclosure, temperatures of 500° C. and 700° C. were evaluated. When the surface was treated at 500° C. for 90 mins, a smooth surface was formed with scattered 100 to 300 nm island-like structures, as shown in FIG. 16(a). At 700° C., an apparently smoother surface resulted with finer granular structures, as shown in FIG. 16(b). The diameters of CNTs depend upon the size of the catalyst granules on the substrate. In the disclosed testing, the average diameter of CNTs varied from 40 to 80 nm (with a few as large as 80 to 120 nm) when the surface was treated at 500° C. In contrast, when the surface was treated at 700° C., CNTs were 10 to 40 nm in diameter (with few in the range of 50-80 nm). The SEM image shown in FIG. 16(c) reveals decreased CNT density when the substrate was treated at 500° C. On surfaces pretreated at 500° C., the CNTs were interspersed with larger amounts of amorphous carbon with high percentages of CNTs found only along a small length at the entrance end of the tubing. The surfaces pretreated at 700° C. revealed more complete surface coverage of CNTs (as shown in FIG. 16(d)) along the entire length, even in testing that involved a 1 minute deposition time. The thickness of the CVD coating at a 500° C. pretreatment temperature was about two to three times less than the thickness observed at 700° C.

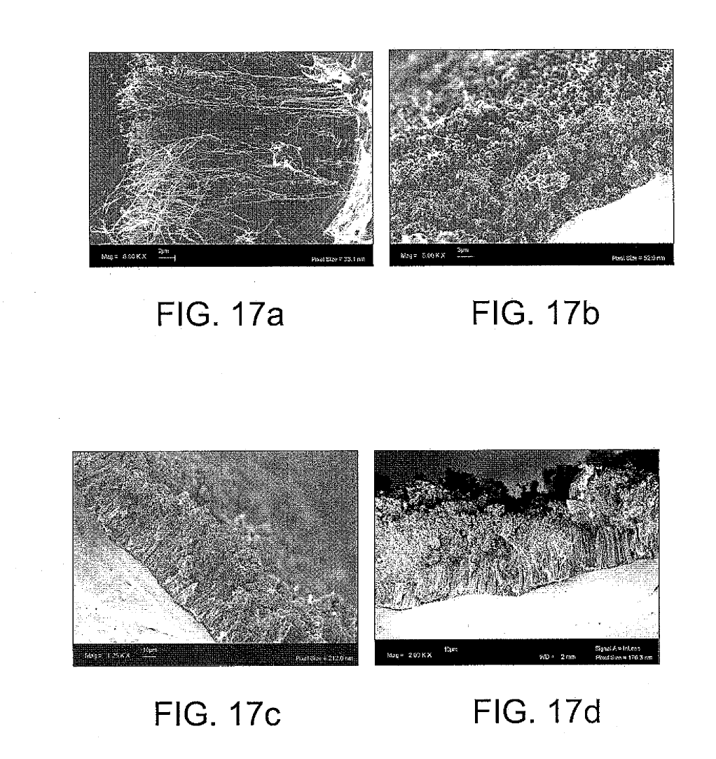

FIG. 17 illustrates the variation in deposition morphology at distances of about 20 cm and 40 cm away from the entrance of the tube. SEM images set forth in FIG. 17(a) and FIG. 17(b) correspond to surface conditioning at 500° C., and a CVD time of 5 mins. As shown in the image of FIG. 17(a), the carbonaceous products consist almost entirely of CNTs interspersed with only very small amounts of NTCs. In contrast, the SEM image of FIG. 17(b) shows amorphous carbons interspersed with fewer CNTs, thus showing significant variations in deposition uniformity. The SEM images of FIG. 17(c) and FIG. 17(d) correspond to surface conditioning at 700° C. with the same CVD time of 5 min. The images demonstrate that the surface coverage of CNTs is substantially uniform. The CNT layers depicted in the noted SEM images contain a layer of amorphous carbons with a thickness somewhat higher in the section of the tubing that is further down from the entrance.

From a mechanistic standpoint, the SEM images and related results/observations disclosed herein are useful in assessing potential CNT growth mechanisms and mechanisms for formation of carbonaceous materials on top of the CNTs. More particularly, a diffusion mechanism is suggested for the growth of CNTs, e.g., based on the thickness of the CVD coating. Lower pretreatment temperatures resulted in lower coating thickness at a given flow rate and CVD time, whereas finer grain structures at the higher temperatures facilitated greater diffusion of carbon into the metal surface. When the solubility of the carbon reaches a critical point, the excess carbon begins to precipitate, lifting the metal particles at its tip. The precipitated carbon continues to grow into a tubular structure with or without the metal particle at its tip. The size of the catalytic metal structure also determines the width or diameter of the CNTs. An amorphous overcoat over the CNT layer is developed because, once the entire bulk metallic surface is covered with dense CNTs, the carbon no longer has access to the catalyst and precipitates as non-tubular amorphous carbon.

An important inference drawn from the formation of the amorphous carbon over the CNT layer is that the carbon feed for the CNT growth is supplied at the surface/root (as in a base-growth model) rather than at the top (as in a tip-growth model). If the carbon supply were at the top (as in a tip growth model), then it would be expected to lead to relatively longer CNTs (until the force of its weight would cause it to bend over and lose its vertical alignment). However, this phenomenon is not observed. Rather, the non-tubular amorphous overcoat started to form once the carbon feed stock failed to access the surface after the CNT grew to a specific length, thus supporting a base-growth model.

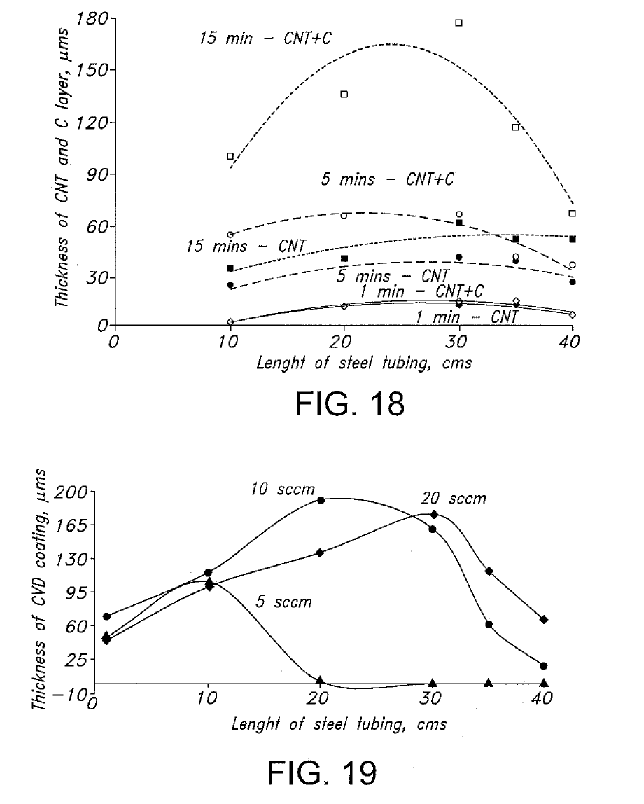

Table 6 (below) summarizes the average thickness±standard deviation (SD) of the CVD coating and the CNT layer, respectively, measured by SEM at 1, 3.5, 5, 15 and 30 mins duration of CVD at a flow rate of 20 sccm of ethylene. The tubing was pretreated at 700° C., and five samples were analyzed along the length of the tubing. FIG. 18 shows the trend of average thickness of the CNT layer with the non-tubular overcoat at 1, 5 and 15 min deposition times. Results from other CVD times showed similar results. The data reflected in FIG. 18 suggests that the thicknesses of the CNT layer and the amorphous carbon layer increase with increased deposition time. The thickness of the deposited film is not uniform but rather graduated, passing through a maximum. The thickness of the coating does not vary significantly at short CVD times, but the variation is considerable at longer deposition times. With an increase in CVD time from 1 min to 15 mins, the thickness of the CNT layer increases. In observed results, the thickness of the carbon layer at 1 min CVD time was between 1 to 2 μm. The thickness increased to about 60 μm for CVD time of 15 mins.

TABLE 6
Total thickness (CNT + C) and the thickness of the CNT layer (CNT) (avg ± SD) in μms
along the length of the tubing at different CVD times, and at 20 sccm flow of ethylene.

| | Thickness of CVD coating (μms) along the length (cms) in the inside of stainless steel tubing at | | | | | | | | | |
|---|---|---|---|---|---|---|---|---|---|---|
| | various CVD durations | | | | | | | | | |
| CVD duration | (cms) 10 | | 20 | | 30 | | 35 | | 40 | |
| (mins) | CNT + C | CNT | CNT + C | CNT | CNT + C | CNT | CNT + C | CNT | CNT + C | CNT |
| 1 | 4 ± 1 | 4 ± 1 | 13 ± 4 | 13 ± 4 | 15 ± 4 | 13 ± 4 | 15 ± 4 | 13 ± 4 | 7 ± 4 | 6 ± 3 |
| 3.5 | 33 ± 4 | 16 ± 3 | 50 ± 7 | 25 ± 7 | 50 ± 7 | 25 ± 7 | 17 ± 4 | 15 ± 4 | 8 ± 3 | 5 ± 2 |
| 5 | 55 ± 7 | 25 ± 7 | 65 ± 7 | 30 ± 7 | 65 ± 7 | 40 ± 7 | 40 ± 7 | 38 ± 4 | 35 ± 7 | 25 ± 7 |
| 15 | 100 ± 7 | 35 ± 7 | 135 ± 14 | 40 ± 7 | 175 ± 14 | 60 ± 14 | 115 ± 14 | 50 ± 7 | 65 ± 7 | 50 ± 7 |
| 30 | 30 ± 7 | 13 ± 4 | 55 ± 7 | 28 ± 4 | 213 ± 17 | 55 ± 14 | 213 ± 17 | 55 ± 7 | 213 ± 17 | 55 ± 7 |

FIG. 19 summarizes the effect of flow rate of ethylene on thickness of the CVD coating, and surface coverage along the length of the tubing. The data reflected in FIG. 19 shows the average coating thickness at 5, 10 and 20 sccm of flow of ethylene and at 15 mins CVD time. For these exemplary test results, the tubing was pretreated at 700° C. Six samples were analyzed along the length of the tubing. At a CVD time of 5 min and flow rates of 5 sccm and 10 sccm of ethylene, surface coverage was seen only in the first half of the tubing, while the other half was practically uncoated. At flow rates of 10 sccm and higher CVD times (e.g., 15 mins), coating was obtained along the entire length of the tubing. At flow rates of 20 sccm, the entire length of the tubing showed a CVD coating with surface coverage after just 1 min. of deposition time. The plot in FIG. 19 shows that the coating thickness peaked at different locations at different flow rates, although at higher flow rates the coating tended to be more uniform. Indeed, higher flow rates of the carbon precursor at shorter CVD times may be effective to provide a near uniform thickness CVD coating over the entire tube length.

In exemplary embodiments of the present disclosure, the thickness of a CNT coating at a given CVD time is influenced by flow rate of the carbon source. In particular, the flow rate affects the residence time and the number of active molecules available for decomposition per unit time. Lowering the flow rate decreases the number of gas molecules undergoing decomposition per unit time, and also decreases the residence time, which is defined as the time that a gas molecule spends in the tube: τ=(π.d²/4.L)/F, where τ is the residence time of the gas molecule, d is the internal diameter of the circular metallic tubing, L is the length of the tubing subjected to high temperature, and F is the flow rate of the gas.

At high temperatures, the longer residence time facilitated rapid and higher decomposition of the molecules to form the carbonaceous products before they could travel further. This phenomenon explains the absence of any coatings at lower flow rates in the later section of the tubing (FIG. 19). At higher flow rates, the number of available precursor molecules is higher, thus subjecting more molecules to decomposition at a given time. At the same time, higher flow rates allowed the molecules to travel further before they decomposed, which explains the higher thickness and increased surface coverage at higher flow rates, as shown in FIG. 19.

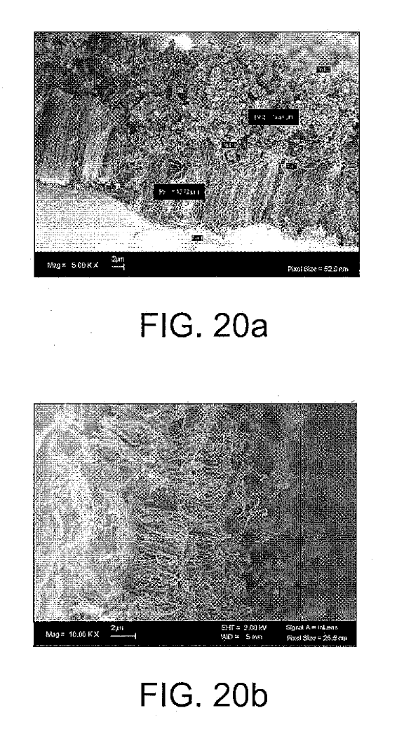

In exemplary embodiments of the present disclosure, thermal annealing in the presence of oxygen or air at relatively low temperatures can be utilized to selectively burn off NTCs. Testing of potential burn off temperatures revealed that heating in the presence of oxygen at 375° C. did little damage to the CNTs, but effectively burnt off the non-tubular carbon overcoat. A thick overcoat of amorphous carbon (formed through CVD treatment of 5 min duration over a 2 ft long tubing) is shown in FIG. 20(a). It took 24 hrs to burn-off and expose the lower CNT layer, as seen in FIG. 20(b). A greater burn-off time may be required for samples deposited with CVD times longer than 5 mins, in which case the thickness of the amorphous carbon overcoat could be higher. At some locations where the thickness of the amorphous carbon was lower, the burn-off damaged some of the CNTs, although often with negligible impact. At temperatures higher than 500° C., both the CNTs and the carbon products are burnt off in 4 hrs. Oxidation in the presence of air, however, takes a longer time to burn the non-tubular overcoat.

Thus, the disclosed apparatus, systems and methods are effective for self-assembly of carbon nanotubes based on CVD of a carbon source, e.g., ethylene, on a substrate/surface, e.g., the inside wall of relatively long stainless steel tubings. TEM images can be used to indicate, verify and/or quantify the presence of MWNTs. Surface conditioning of the substrate/surface, e.g., steel tubing, may be used to generate nanostructured iron, which is an effective catalyst for CNT growth. The CNTs are vertically aligned and are often accompanied by the formation of an amorphous carbon or other NTC overcoat. SEM images of exemplary embodiments show that the thicknesses of the amorphous carbon overcoat and the CNT layer vary along the length of the surface/substrate (e.g., tubing), and that the variation increases with the duration of CVD. Thermal annealing in the presence of oxygen allows for the selective oxidation of the NTC overcoat leaving the CNT layer intact. The flow rate of the carbon precursor influences surface coverage and thickness of the coating, with higher flow rates leading to better coverage and a more uniform film thickness. Results and observations have also demonstrated that self-assembly of CNTs is possible on relatively large structures, thereby facilitating implementation in large-scale applications.

In exemplary embodiments, including all aforementioned embodiments, functionalization of the CNTs may be allowed, enabled or facilitated. Functionalizing CNTs alters the ability of the CNTs to interact and/or react specifically/selectively with environmental factors and constituents. In such embodiments, functionalization can be carried out at any time before, during or after the deposition process. Thus, in exemplary embodiments, functionalization may follow the self-assembly of the CNTs on the selected medium. Functionalization may transpire as a result of or through a variety of methods and techniques.

The disclosed CNTs may be effectively used as a high performance separation media due to inherent nanoscale interactions. There are many advantages to using self-assembled CNT and, in particular, SWNT as the basis for the stationary phase of high performance separations. The advantageous properties and/or characteristics of the disclosed embodiments include, but are not limited to, excellent column efficiency, effective separation, stability, reusability, high resolution (even at high temperatures), high capacity, versatility, extended range of separable matter, ease of fabrication, alterability and controllability of column attributes, and effectiveness over a wide range of analytes and dissimilar analyte combinations.

One particular advantage of the present disclosure is that a CNT film results in an excellent chromatography stationary phase and/or can be used as an effective separation media. CNT films are stable and can handle temperature cycling associated with typical GC applications. To this end, the same synthesized GC column can be used for months. Typically, there is no column bleed and the base lines are stable. A wide range of organic molecules may be separated on these CNT-based columns.

Excellent column efficiency makes CNTs an extremely attractive chromatography stationary phase. The increased efficiency is due, at least in part, to the large aspect ratio and higher surface area characteristic of CNTs. SWNTs are particularly efficient because they are significantly smaller in diameter than MWNTs and are known to possess particularly advantageous properties, e.g., advantageous electrical properties.

High-performance stationary phases that provide high resolutions and are stable at high temperatures are of significant importance in GC analysis. Using CNTs as the stationary phase for GC achieves both high resolution and stability at high temperature which, accordingly, extends the range of conventional chromatography on the same column and permits separations of higher molecular weights at higher temperatures. Two aspects of CNTs are important for chromatography, namely, adsorption and fast desorption to achieve separation within a reasonable time and at high resolutions. These advantages arise primarily due to the high surface area of CNTs characterized by the inner hollow cavity of CNTs, the outside surface of the CNTs and the interstitial spaces between the nanotube bundles, all of which facilitate adsorption.

Varied affinity and selectivity for a wide range of analytes may be possible with CNTs based upon their size, diameter, form (SWNTs or MWNTs), functionalization, and film thickness which makes the presently disclosed embodiments very versatile. The high versatility is characterized by the ability to separate a wide range of molecules. The presently disclosed embodiments are applicable for separations at high resolution of a variety of compounds with varying polarity and varying molecular weights, including low molecular weight C₁ to C₆ alkanes (and larger molecular weights, such as C₆ to C₁₄ alkanes) and polyaromatic hydrocarbon (PAH) mixtures. The versatility and breadth of applicability of the disclosed CNT-based embodiments are particularly advantageous because in conventional systems, separation of the former would be carried out in a packed GC column and separation of the latter would be carriet out in open tubular columns.

A CNT-based stationary phase thus allows for all separations to be carried out in a single open tubular format, often times resulting in significantly higher resolution. Thus, the presently disclosed embodiments are applicable to separate analytes with a wide range of boiling points and volatility, attributes generally not available in other gas chromatography techniques. The ability to separate analytes with varying boiling points and volatility may be attributable to the stability of the CNTs, most particularly SWNTs, at high temperatures. Thus, the presently disclosed embodiments can be applied to a variety of separations, such as halohydrocarbons, alcohols, ketones, and alkane isomers. Present embodiments also allow for the separation of relatively less volatile compounds, such as benzene and toluene. Also of note, SWNT-based columns exhibit greater interaction with organic vapors relative to commercially available stationary phases, such as a Carbopack C™ column. This may be due to the fact that SWNTs can be utilized to generate a non-polar stationary phase.

Another advantage of exemplary embodiments of the present disclosure is that self-assembly CNTs results in a high performance separation media. More particularly, SWNT-based separations produce nearly symmetrical peaks and comparable retention times as compared to a commercial carbon phase columns, such as a Carbopack C™ column. CNT-based separations exhibit classical chromatographic behavior with correlation coefficients of 0.99. The presently described apparatus, systems and methods also enable implementation of reliable and reproducible techniques. Indeed, the typical reproducibility in retention time measured as relative standard deviation (RSD) is <2%, which is comparable to the reliability of commercially available GC columns. Additionally, CNT-based separation exhibits no column bleed or other instability at higher temperatures.

A major advantage is the ease of fabrication by the self-assembly of CNTs directly on the tube surface. The nanostructured metal catalyst developed on the tube surface effectively anchors the CNTs, leading to the formation of a stable stationary phase.

The ability to alter the attributes of the CNT column is another advantage. The thickness of the CNT film and its morphology can be tailor-made by varying applicable parameters, e.g., the CVD precursor, the catalyst preparation and by chemical functionalization. This can lead to development and/or fabrication of a wide range of chromatographic columns with variable selectivity.

It is further noted that the highly desirable sorbent characteristics of CNTs makes them attractive for a variety of alternative applications, including micro-scale preconcentration of organics. In this respect, the high aspect ratio of CNTs leads to large specific capacity. At the same time, unlike conventional carbon based sorbents, CNTs are non-porous tubular structures, thus eliminating the mass transfer resistance related to diffusion into pores. Sorption characteristics of select organics on SWNTs and MWNTs that are packed and self-assembled onto micro-sorbent traps illustrate the applicability and beneficial utility of CNTs for such applications. Indeed, the data demonstrates that adsorption as well as desorption are highly favorable on CNTs, with adsorption being characterized by relatively large breakthrough volumes and isosteric heats of adsorption (ΔHₛ close to 64 kJ/mole), while rapid recovery was demonstrated by narrow desorption band widths. Elimination of nontubular carbonaceous impurities from the CNT surface improves sorbent performance.

The sorption sites on CNTs are on the wall and in the interstitial spaces between tubes. These sites are easily accessed for both adsorption and rapid desorption. Potential NTC coverage on CNTs reduces their availability, as the sorbate has to diffuse through the NTC to reach the CNT. Moreover, the porous structure of NTC introduces mass transfer limitations, slowing both adsorption and desorption. The disclosed CNTs are well-suited for micro-scale devices, e.g., microconcentrators and/or micro-sorbent traps. Such devices may act as fast preconcentrator or to modulate the concentration of a stream for real-time monitoring.

Breakthrough and desorption efficiencies are important characteristics of a micro-sorbent trap, i.e., a microtrap. Because of its small dimensions, only a small amount of sorbent can be accumulated inside, thus, making it prone to breakthrough. For quantitative sampling, the sample volume should not exceed its breakthrough volume, which may be defined as the volume that can be sampled per unit weight of the sorbent before the analyte is lost. Previous studies have suggested that for a trap with a large number of theoretical plates, the breakthrough is independent of the analyte concentration. Microtraps are generally designed to be small, so that they have large number of plates and can be heated rapidly. Therefore, microtraps are packed with a small amount of sorbent and are often designed to retain the analytes only for a few seconds/minutes before rapid desorption. So, both adsorption and desorption play important roles in a fast acting microtrap. According to the present disclosure, CNT sorbents can be used in a microtrap in a packed format, or as a self-assembled trap. The packed format facilitates the use of a larger amount of sorbent, while the self-assembled trap provides an ordered nanostructure.

The test data set forth below is directed to the sorption of select volatile organics on SWNT, MWNT and self-assembled CNTs. The data is useful in evaluating the relative effectiveness of various CNTs as analytical sorbents and their applicability in a micro-sorbent trap, i.e., a microtrap.

### Experiment

A MWNT sample synthesized by CVD using ethanol as a precursor and Ni as catalyst was obtained from Chaing Mai University. This sample, which had not been standardized and which contained significant NTC, is referred to as MWNT-1. To eliminate the NTC and purify the CNTs, the sample was first passed through a 106 micron sieve (Endecott, Ltd, England) to eliminate the large particles. The NTC that remained on the CNT surface was removed by selective oxidation in a flow of air at 300° C. for 30 minutes. The cleaned MWNT-1 was referred as MWNT-1C. Purified SWNT and MWNT (referred to as MWNT-2) were purchased from Cheap Tubes Inc. A Carbopack™ column, which was purchased from Supelco Inc., was used as a control.

Microtrap Fabrication: The CNTs and Carbopack™ column were packed inside a 0.5 mm ID capillary to form a microtrap. Mechanical shaking using a vibrator was used to obtain a uniform packing. Each microtrap was packed with 20 mg of the sorbent. A self-assembled CNT microtrap was fabricated as follows: (i) steel tubing was heated in air a 10 mL/min flow at 500° C. for 30 min to oxidize the surface; (ii) the surface was reduced in a 10 mL/min flow of H₂ at 500° C. for 30 min—the oxidation and reduction led to the formation of a catalytically active surface; (iii) chemical vapor deposition (CVD) was carried out at 700° C. for 1 hr using C₂H₄ as the precursor; and (iv) to remove the NTC from CNT surface, thermal annealing in the presence of oxygen was carried out at 350° C. at a flow rate of 300 mL/min.

Scanning electron microscopy (SEM) using Model Genesis 4000 XMS (EFI, USA) was used to study the MWNT-1 and MWNT-1C. The SEM image of the self-assembled CNTs was obtained using a Leo 1530 VP (Carl Zeiss SMT AG Company, Oberkochen, Germany).

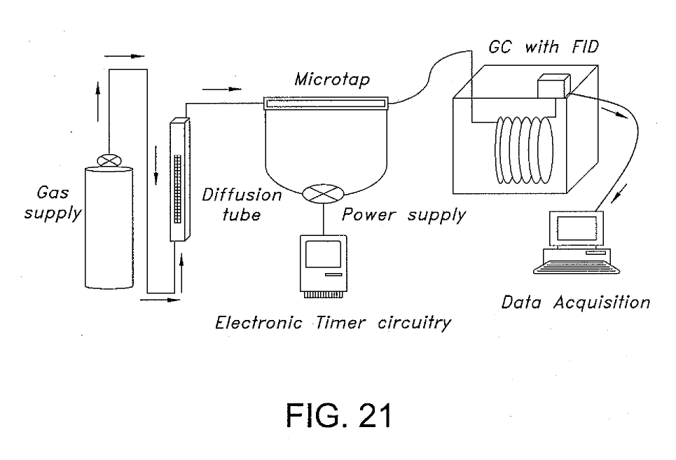

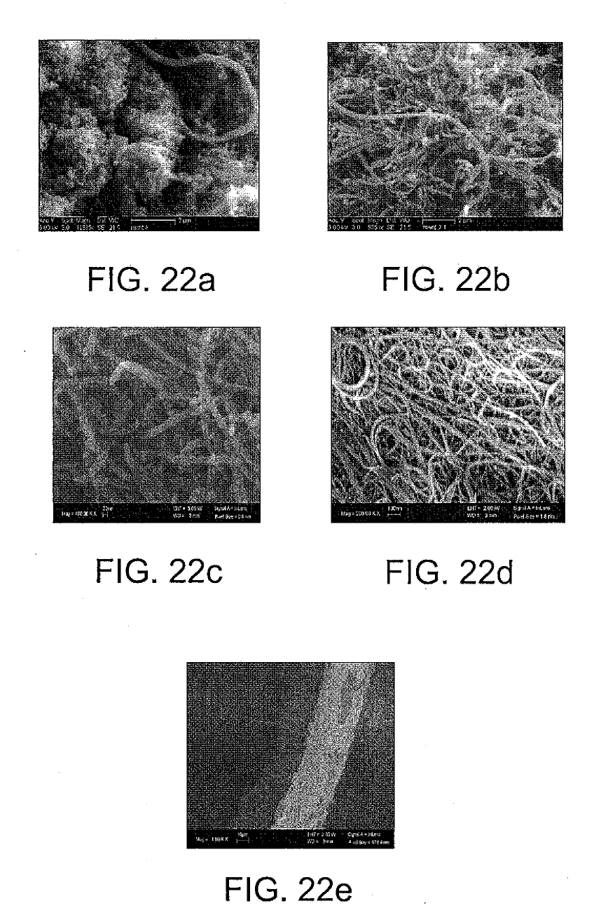

The experimental system used to generate the experimental results reported herein is schematically depicted in FIG. 21. Parts per million level organic standards were generated using a diffusion tube method. The N₂ stream containing the organics flowed through the microtrap continuously and were retained by the sorbents. Desorption pulses at fixed intervals were applied to the microtrap, so that the trapped organics were desorbed and detected by the GC. The microtrap was resistively heated with a 7-10 ampere pulse of electric current from a power supply (Variac 100/200 Series). Typical duration of the electric pulse was between 1 and 1.5 seconds, and intervals varied between 2 and 20 minutes. An electric timer (Variac ATC 305) was used to control the frequency of injections. Different desorption temperatures were achieved by increasing either the voltage or the duration of heating. Gas Chromatograph (Varian 3400) equipped with a conventional flame ionization detector (FID) was used for analysis using a 0.53 mm internal diameter, 30 m capillary column (DB-624, J&W Scientific). Nitrogen was used as the carrier gas at a flow rate of 3 mL/min.

Purification of CNTs: FIG. 22(a) shows an SEM image of the MWNT-1 sample which appears to be covered with NTC, including large agglomerates of several microns in diameter. With few available CNT sites, much of the adsorption can be expected on the NTC regions. Different purification strategies were employed to clean MWNT-1. FIG. 22(b) is an SEM image of MWNT-1C, which was cleaned by sieving to remove the large particles, and then by oxidation in air at 350° C. to eliminate amorphous carbon on the surface. This preparation showed mainly CNTs with some residual NTC. Too long an exposure to air at high temperature led to the oxidation of the MWNT as well, so the heating time was limited to 30 minutes. With these two purification steps, the availability of the active CNT sites increased dramatically.

SEM images of MWNT-2 and SWNT samples are presented in FIG. 22(c) and FIG. 22(d), respectively, which show relatively pure preparations that did not require any preprocessing. The length of the CNTs ranged from a few hundred nanometers to micrometers, while the average diameter ranged from 10-20 nm for SWNT and 20-40 nm for MWNT-2, respectively.

FIG. 22(e) is a SEM image of self-assembled CNTs inside a microtrap. This SEM image was acquired after oxidative cleaning by passing air at 350° C. The CNTs were vertically aligned in a forest-like structure providing excellent sorption sites. The average diameter for self-assembled CNTs were much smaller than the MWNT-1C sample. The film thickness of self-assembled CNTs was found to be about 20 microns and the CNTs were uniformly distributed throughout the microtrap.

Breakthrough Characteristics of the Microtrap: As N₂ gas continuously flowed through the microtrap, the organics already trapped in the microtrap began to migrate because the N₂ acted as an eluent. The sorption capacity of the CNTs in the microtrap was evaluated by studying the breakthrough time of the microtrap. Breakthrough time may be defined as the time required by an analyte to elute through or the time for which the organics are retained on the CNTs. Breakthrough time is generally a function of capacity factor, length and flow rate. The breakthrough time was measured by operating the microtrap at different injection intervals. Increasing injection interval enhanced the detector response as more organics were accumulated by the microtrap. Once the VOCs began to breakthrough, the response did not increase any further with the interval. Accordingly, the breakthrough time of the microtrap was computed as the time required to reach the maximum response.

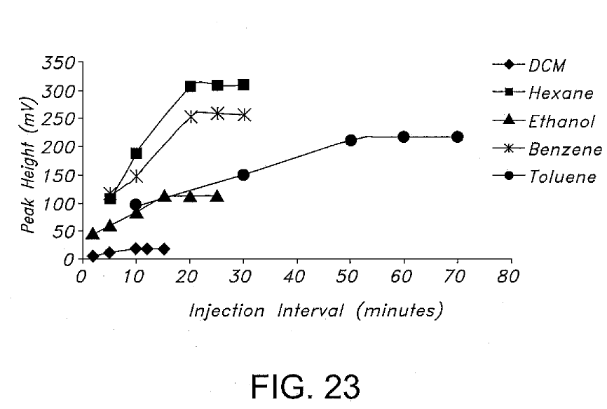

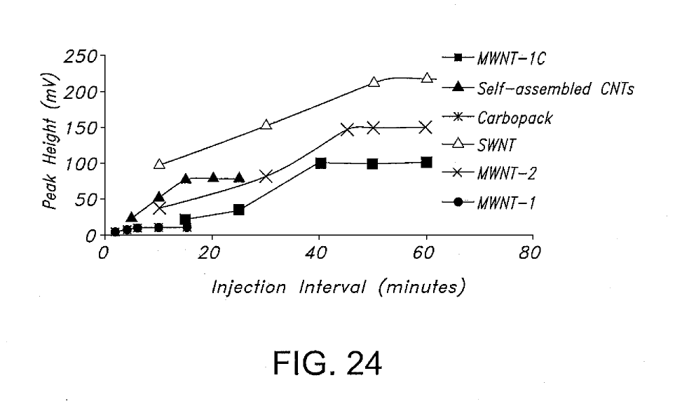

Five organics containing different functionalities representing a wide range of volatilities were tested. Typical breakthrough profiles for SWNT are seen in FIG. 23, with toluene showing the longest breakthrough time. Sorption on other CNTs (not pictured) were similar. A comparison of different sorbents with respect to toluene retention is shown in FIG. 24. For the same mass of sorbent, all CNT microtraps showed significantly higher sorption capacity as compared to the control Carbopack™ column, i.e., the only non-nanotube sorbent in the tested group. The impure MWNT-1 sample with a large amount of NTC was similar in performance to the Carbopack™ sample. This performance may be explained because much of the adsorption in the MWNT-1 sample occurred on the NTC impurities which are morphologically closer to the Carbopack™ sample than the disclosed CNTs. Indeed, purification to MWNT-1C led to a 600% increase in breakthrough time for toluene, demonstrating the importance of impurity elimination in connection with CNT performance. The self-assembled CNTs showed relatively high sorption capacity despite the fact that it was only a 20 μm thick film and represented a relatively small quantity of CNTs.

The breakthrough time for different compounds on different sorbents are set forth in Table 7 (below). The SWNT sample showed the highest adsorption capacity in terms of breakthrough volume. This is attributable to the higher aspect ratio due to the smaller diameter, which led to a higher specific area. For example, the breakthrough time of methylene chloride (DCM) on the SWNT sample was five (5) times higher than that on the Carbopack™ control or the MWNT-1 sample. The MWNT-1C sample showed breakthrough times that were closer to the MWNT-2 sample, but were consistently lower. This may be attributed to higher impurities in the former sample, along with other factors, such as, different size and morphology. The retention of benzene was lower than expected, but that of xylene was quite high.

TABLE 7
Breakthrough times (minutes) for different sorbents and analytes.

| Type of | | | | | | |
|---|---|---|---|---|---|---|
| Microtrap | DCM | Ethanol | Hexane | Benzene | Toluene | Xylene |
| MWNT-1C | 5 | 10 | 15 | 15 | 40 | 120 |
| MWNT-2 | 8 | 12 | 20 | 20 | 45 | 120 |
| SWNT | 10 | 15 | 20 | 20 | 50 | 120 |
| MWNT-1 | 2 | 2 | 5 | 6 | 6 | 10 |
| Carbopack | 2 | 2 | 5 | 6 | 6 | 10 |
| Self-assembled | 2 | 5 | 6 | 10 | 15 | 20 |
| CNTs | | | | | | |

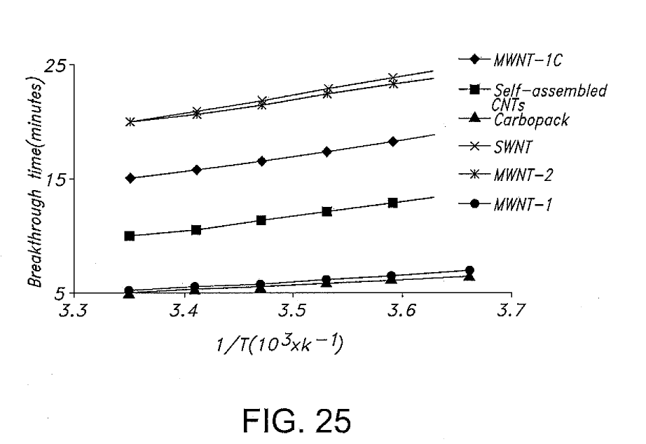

Breakthrough Time as a Function of Temperature: Adsorption is an exothermic phenomenon and the breakthrough time of a compound is inversely proportional to the temperature. Accordingly, when adsorption temperature was decreased, the breakthrough time increased. The results followed the Van't Hoff-type relationship, as shown in FIG. 25. Of note, the slopes varied for different sorbents, with the SWNT sample exhibiting the largest slope and the Carbopack™ sample exhibiting the smallest slope.

The isosteric heat of adsorption, ΔHₛ, is the amount of heat released when an atom adsorbs on a substrate, and is related to the activation energy of sorption for a sorbate-sorbent system. The strength of interaction of compound with the surface of the of the adsorbent (CNTs) is represented by the enthalpy of adsorption, ΔHₛ. The maximum ΔHₛ value was found with the SWNT sample, suggesting that it had the strongest interaction with the analyte. This was followed by the MWNT-2 and MWNT-1C samples. The MWNT-1 and Carbopack™ samples showed similar values of ΔHₛ, which were about one third that of the SWNT sample. These results further demonstrate that the mechanisms of adsorption were quite similar in the unpurified MWNT-1 and control samples. Of note, the ΔHₛ values followed a trend similar to that of the breakthrough times for the different analytes.

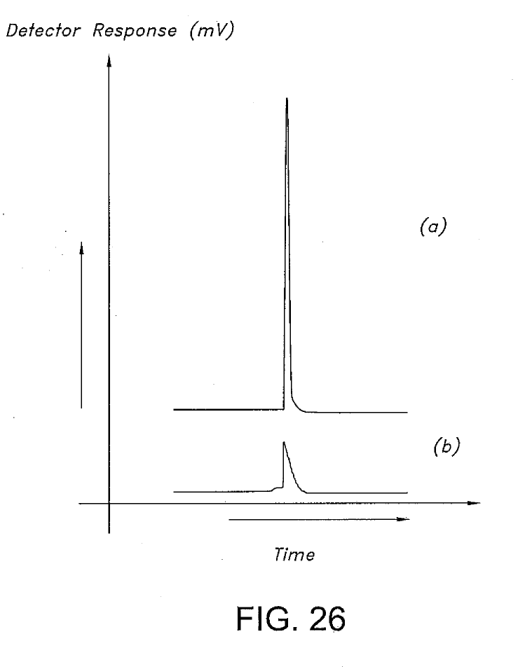

Quantitative Desorption from the Microtrap: The desorption of organics is also an important performance parameter according to the present disclosure. Desorption was tested by passing a pulse of electric current directly through the wall of the microtrap. For quantitative desorption, a threshold energy level must be provided. FIG. 26 provides a typical desorption profile generated from these sorbents (for benzene). The peak width is a measure of the ease of desorption, and is also an important parameter in chromatographic separation.

Table 8 (below) provides an interesting insight into the desorption of toluene and benzene from all tested sorbents. Due to mass transfer issues related to porous structures, both the MWNT-1 and Carbopack™ samples showed the widest desorption bands, implying slow release of solutes. The desorption peak widths were lowest for the SWNT sample. For toluene at 3 ml/min, the difference was 29%. However, for benzene at a 6 ml/min, this difference increased to more than 3.5 times. The very low desorption band widths for the SWNT, MWNT-2 and MWNT-1C samples demonstrates that CNTs are excellent sorbents that are also relatively easy to desorb. Accordingly, CNTs can be expected to provide superior desorption efficiency. Overall, the test results reported herein show that CNTs not only have high adsorption capacity but also are desorbed easily.

TABLE 8
Peak width at half height for toluene and benzene

| | Toluene¹ | Benzene² |
|---|---|---|
| Type of Microtrap | (Seconds) | (Seconds) |
| Self-assembled CNTs | 1.88 | 0.28 |
| MWNT-1C | 1.87 | 0.28 |
| MWNT-2 | 1.7 | 0.27 |
| SWNT | 1.6 | 0.26 |
| MWNT-1 | 2.05 | 1.87 |
| Carbopack ™ Control | 2.06 | 1.89 |

¹Flow rate of 3 mL/minutes
²Flow rate of 6 mL/minutes

Based on the experimental results set forth herein, the sorption characteristics of select organics on single and multi-walled carbon nanotubes packed and self-assembled onto microtraps demonstrate that adsorption as well as desorption were highly favorable for the CNT samples. The elimination of nontubular carbonaceous impurities from the CNT surface was beneficial, because the presence of such impurities negatively impacted upon sorbent performance. An impure CNT preparation was closer in performance to the control Carbopack™ sample than either of the clean SWNT or MWNT samples. The high capacity of the CNTs was seen from breakthrough volumes that were as much as 12 times higher than the control sorbent, while the isosteric heats of adsorption (ΔHₛ) for benzene was 3.5 times higher. Rapid recovery from the CNTs was demonstrated by narrow desorption band widths. The breakthrough volumes and the injection band widths on the SWNT and the MWNT samples were similar and significantly more favorable than the control sorbent.

Although the present disclosure has been described with reference to exemplary embodiments and implementations thereof, the present disclosure is not to be limited by or to such exemplary embodiments and/or implementations. Rather, the systems and methods of the present disclosure are susceptible to various modifications, variations and/or enhancements without departing from the spirit or scope of the present disclosure. Accordingly, the present disclosure expressly encompasses all such modifications, variations and enhancements within its scope.

1. A method for synthesizing a sorbent on a substrate, comprising:
a) providing a substrate;
b) self-assembling carbon nanotubes on the substrate by chemical vapor deposition.

2. The method of claim 1, wherein the carbon nanotubes are selected from the group consisting of single wall carbon nanotubes, multiwalled carbon nanotubes, and combinations thereof.

3. The method of claim 1, wherein the substrate includes a length of tubing and wherein the carbon nanotubes are formed on an inner surface of said tubing.

4. The method of claim 1, further comprising providing a catalyst for chemical vapor deposition of the nanotubes on the substrate.

5. The method of claim 4, wherein the catalyst is iron that is present in the substrate.

6. The method of claim 4, wherein the catalyst is external to the substrate.

7. The method of claim 6, wherein the external catalyst is selected from the group consisting of cobalt, molybdenum and nickel.

8. The method of claim 1, further comprising fabricating a separator from the substrate.

9. The method of claim 8, wherein the separator is a chromatography medium.

10. The method of claim 1, further comprising functionalizing the carbon nanotubes on the substrate.

11. The method of claim 1, further comprising removing residual impurities from the self-assembled carbon nanotubes on the substrate.

12. The method of claim 11, wherein removal of the residual impurities from the self-assembled carbon nanotubes includes oxidation of the residual impurities.

13. The method of claim 12, wherein the oxidation involves bringing an oxidizing agent into contact with the residual impurities.

14. The method of claim 13, wherein the oxidizing agent is selected from the group consisting of air, oxygen and hydrogen peroxide.

15. The method of claim 1, wherein self-assembly of the carbon nanotubes by chemical vapor deposition includes introduction of an organic precursor into contact with the substrate.

16. The method of claim 10, wherein the organic precursor is selected from the group consisting of ethylene, ethane, methane, butane, propane, ethanol, methanol and combinations thereof.

17. The method of claim 1, wherein the substrate is preprocessed to remove impurities therefrom.

18. The method of claim 1, wherein the chemical vapor deposition is catalyzed by an organic solution that includes at least one salt of cobalt and molybdenum dissolved therein.

19. A substrate with self-assembled carbon nanotubes formed thereon according to the method of claim 1.

20. A sorbent structure, comprising:
a) a substrate that defines a surface; and
b) self-assembled carbon nanotubes formed on the surface of the substrate;
wherein the self-assembled carbon nanotubes are effective for high-resolution separation.

21. The sorbent structure according to claim 20, wherein the substrate is a chromatography media.

22. The sorbent structure according to claim 20, wherein the substrate is a microtrap.

23. The sorbent structure according to claim 20, wherein the substrate includes a catalyst for self-assembly of carbon nanotubes on the surface thereof.

24. The sorbent structure according to claim 20, wherein the surface of the substrate includes self-assembled carbon nanotubes formed thereon and is substantially devoid of impurities.

25. The sorbent structure according to claim 20, wherein the self-assembled nanotubes are selected from the group consisting of single wall nanotubes, multiwall nanotubes and combinations thereof.

26. The sorbent structure according to claim 20, wherein the self-assembled nanotubes are functionalized.

27. The sorbent structure according to claim 20, wherein the self-assembled nanotubes on the surface of the substrate are adapted to function as an adsorbent for an application selected from the group consisting of gas cleaning, water treatment, pollution control, solute separation, gas storage, concentration of volatile organic compounds, and a chromatographic stationary phase.
